(19) United States
(12) Patent Application Publication
(10) Pub. No.: US 2010/0296003 A1
(43) Pub. Date: Nov. 25, 2010

(54) LAMP HOLDER, ILLUMINATION DEVICE, DISPLAY DEVICE, AND TELEVISION RECEIVER APPARATUS

(75) Inventors: Yasumori Kuromizu, Osaka (JP); Masashi Yokota, Osaka (JP); Syuki Yamamoto, Osaka (JP); Kaori Yamamoto, Osaka (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 12/812,485

(22) PCT Filed: Dec. 10, 2008
(86) PCT No.: PCT/JP2008/072442

§ 371 Date: Jul. 12, 2010

(30) Foreign Application Priority Data
Jan. 22, 2008 (JP) 2008-012021

(51) Int. Cl. H04N 5/44; F21V 21/00; G02F 1/13357; H03H 7/00

(52) U.S. Cl. 348/725; 362/217.14; 362/217.15; 362/225; 349/61; 348/E05.096

(57) ABSTRACT

A lamp clip 18 includes a main body 27 and a lamp gripping portion 28. The main body 27 is mounted to a chassis 14. The lamp gripping portion 28 has an open-end ring shape and is provided on an opposite side of the main body 27 from the chassis 14 so as to grip a tubular cold cathode tube 17 housed in the chassis 14. At least a part of the lamp gripping portion 28 is tapered such that a size that measures in a length direction of the cold cathode tube 17 gradually decreases toward the cold cathode tube 17.

### TECHNICAL FIELD

The present invention relates to a lamp holder, an illumination device, a display device, and a television receiver apparatus.

### BACKGROUND ART

For example, a liquid crystal panel used in a liquid crystal display device such as a liquid crystal television does not emit light by itself, and separately requires a backlight unit as an illumination device. The backlight unit is provided on a back side (on a side opposite a display surface) of the liquid crystal panel, and includes a chassis made of metal or resin and opening on a side of the liquid crystal panel, a reflective sheet provided in the chassis, multiple fluorescent tubes (for example, cold cathode tubes) housed as lamps in the chassis, multiple optical members (diffuser sheets or the like) provided in the opening in the chassis for efficiently emitting lights emitted by the cold cathode tubes toward the liquid crystal panel, and a lamp clip that supports an intermediate portion of each of the cold cathode tubes having an elongated tubular shape. The lamp clip includes a lamp gripping portion for gripping the cold cathode tube on a plate-shaped main body mounted to a bottom plate of the chassis.

When the cold cathode tube is lit, an amount of light of the cold cathode tube is inevitably slightly reduced in the lamp gripping portion, which may cause a part of the main body to be observed as a faint shadow on the liquid crystal panel.

Thus, a technique of preventing occurrence of a shadow on a main body is proposed in Patent Document 1. In this technique, a main body has a triangular sectional shape, a sloped surface is formed on a surface thereof, and the sloped surface can reflect, toward a liquid crystal panel, a light emitted from opposite sides of a portion where a lamp gripping portion grips a cold cathode tube to the main body. This prevents occurrence of a shadow on the main body.

### Patent Document 1: Japanese Patent Laid-Open No. 2005-17691

### DISCLOSURE OF THE INVENTION

### Problems to be Solved by the Invention

To reduce a thickness of a liquid crystal display device, it is necessary to reduce a thickness of each component or reduce a space between components. At this time, if a space between an optical member and a lamp clip is reduced, a dark portion created by the lamp clip tends to be easily visually identified. Thus, there is a possibility that the technique described in Patent Document 1 cannot accommodate a further reduction in thickness of the liquid crystal display device, and further measures have been desired.

The present invention is completed based on the above-described circumstances, and has an object to make a dark portion less likely to be recognized.

### Means for Solving the Problems

A lamp holder of the present invention includes a lamp gripping portion for holding a tubular lamp. The lamp gripping portion has an open-end ring shape with a tapered portion that tapers toward an end thereof located on a lamp holding side.

Thus, even if the lamp is covered by the lamp gripping portion having an open-end ring shape, a covered area is reduced because at least a part of the lamp gripping portion is tapered. This can increase an effective light emitting area of the lamp and increase an amount of light provided by the lamp. Therefore, the lamp gripping portion is less likely to be recognized as a dark portion.

### BRIEF DESCRIPTION OF THE DRAWINGS

FIG. 1 is an exploded oblique perspective view showing an outline configuration of a television receiver apparatus according to a first embodiment of the present invention;

FIG. 2 is an exploded oblique perspective view showing an outline configuration of a liquid crystal display device;

FIG. 3 is a sectional view showing the liquid crystal display device cut along a short side direction;

FIG. 4 is a sectional view showing the liquid crystal display device cut along a long side direction;

FIG. 5 is a front view of a lamp clip;

FIG. 6 is a plan view of the lamp clip;

FIG. 7 is a bottom view of the lamp clip;

FIG. 8 is a side view of the lamp clip;

FIG. 9 is a plan view showing a state where each lamp clip is mounted to a chassis;

FIG. 10 is a plan view of the chassis and a reflective sheet;

FIG. 11 is an enlarged plan view of the chassis and the reflective sheet;

FIG. 12 is a sectional view showing a mounting state of the lamp clip in the liquid crystal display device;

FIG. 13 is a sectional view taken along the line A-A in FIG. 12;

FIG. 14 is a sectional view taken along the line B-B in FIG. 12;

FIG. 15 is a sectional view taken along the line C-C in FIG. 12;

FIG. 16 is a sectional view taken along the line D-D in FIG. 12;

FIG. 17 is a sectional view taken along the line E-E in FIG. 12;

FIG. 18 is a sectional view showing a state before the lamp clip is mounted to the chassis;

FIG. 19 is a sectional view showing a state where a main body is tilted during mounting of the lamp clip;

FIG. 20 is a sectional view showing a state before the main body is slid during mounting of the lamp clip;

FIG. 21 is a sectional view showing a state where the lamp clip is to be mounted in a mounting direction opposite a normal direction, and a first mounting portion interferes with a rim of a second mounting hole;

FIG. 22 is a plan view showing a state where a lamp clip is mounted to a chassis according to a second embodiment of the present invention;

FIG. 23 is a plan view showing a state where a lamp clip is mounted to a chassis according to a third embodiment of the present invention;

FIG. 24 is a plan view showing a state where a lamp clip is mounted to a chassis according to a variation aspect of the third embodiment;

FIG. 25 is a bottom view of a lamp clip according to a fourth embodiment of the present invention;

FIG. 26 is an enlarged plan view of the chassis;

FIG. 27 is a bottom view of a lamp clip according to a variation aspect of the fourth embodiment;

FIG. 28 is an enlarged plan view of the chassis;

FIG. 29 is a side sectional view of a main body of a lamp clip according to a fifth embodiment of the present invention;

FIG. 30 is a side sectional view of a main body of a lamp clip according to a sixth embodiment of the present invention;

FIG. 31 is a side sectional view of a main body of a lamp clip according to a seventh embodiment of the present invention;

FIG. 32 is a side sectional view of a lamp gripping portion of a lamp clip according to an eighth embodiment of the present invention;

FIG. 33 is a side sectional view of a lamp gripping portion of a lamp clip according to a ninth embodiment of the present invention;

FIG. 34 is a side sectional view of a lamp gripping portion of a lamp clip according to a tenth embodiment of the present invention;

FIG. 35 is a side sectional view of a lamp gripping portion of a lamp clip according to an eleventh embodiment of the present invention;

FIG. 36 is a front view of a lamp clip according to a twelfth embodiment of the present invention;

FIG. 37 is a plan view showing a state where the lamp clip is mounted to a chassis;

FIG. 38 is a plan view of a lamp clip according to a thirteenth embodiment of the present invention;

FIG. 39 is a front sectional view showing a state where a lamp clip is mounted to a chassis according to a fourteenth embodiment of the present invention;

FIG. 40 is a plan sectional view of a holding protrusion on a lamp gripping portion of a lamp clip according to a fifteenth embodiment of the present invention;

FIG. 41 is a plan sectional view of a holding protrusion according to a variation aspect of the fifteenth embodiment;

FIG. 42 is a front view of a lamp clip of further embodiments (1) and (5);

FIG. 43 is a plan view of the lamp clip of other embodiments (1) and (5); and

FIG. 44 is a plan view of a chassis of another embodiment (9).

### BEST MODE FOR CARRYING OUT THE INVENTION

### First Embodiment

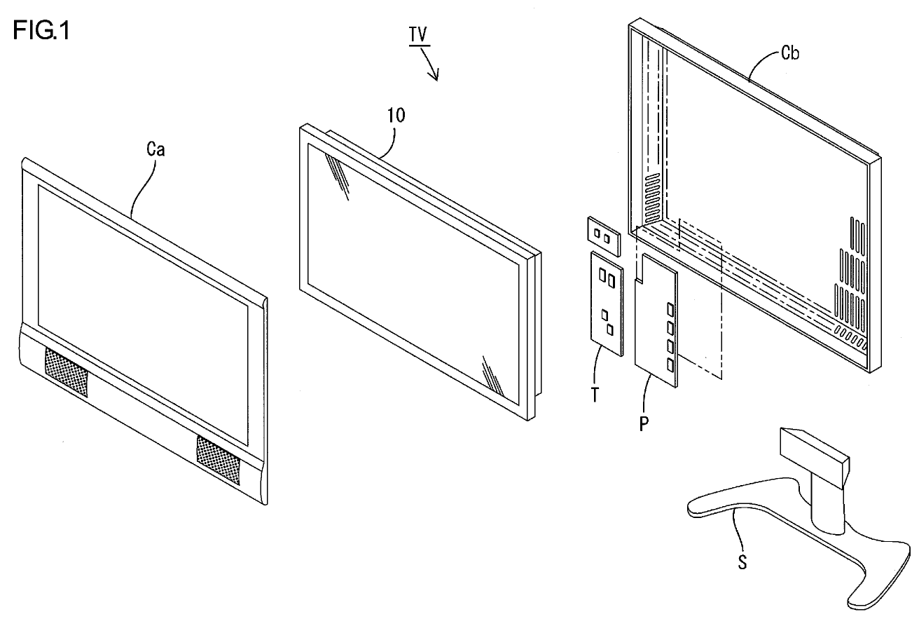

A first embodiment of the present invention will be described with reference to FIGS. 1 to 21.

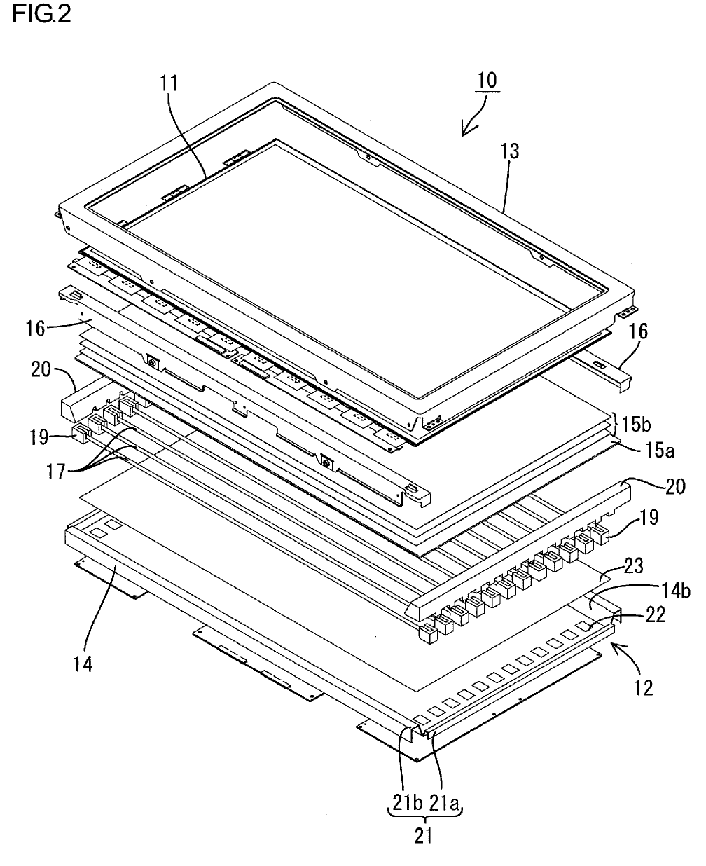

A television receiver apparatus TV according to this embodiment includes, as shown in FIG. 1, a liquid crystal display device 10, front and back cabinets Ca and Cb that hold and house the liquid crystal display device 10 therebetween, a power source P, a tuner T, and a stand S. The liquid crystal display device (display device) 10 generally has a horizontally oriented rectangular shape, and is housed in a vertically placed state. The liquid crystal display device 10 includes, as shown in FIG. 2, a liquid crystal panel 11 as a display panel, and a backlight unit (illumination device) 12 as an external light source, which are integrally held by a frame-shaped bezel 13 or the like. In a part of the drawings, an X-axis, a Y-axis, and a Z-axis are shown so that axial directions are in directions shown in the drawings.

Next, the liquid crystal panel 11 and the backlight unit 12 that constitute the liquid crystal display device 10 will be described (see FIGS. 2 to 4).

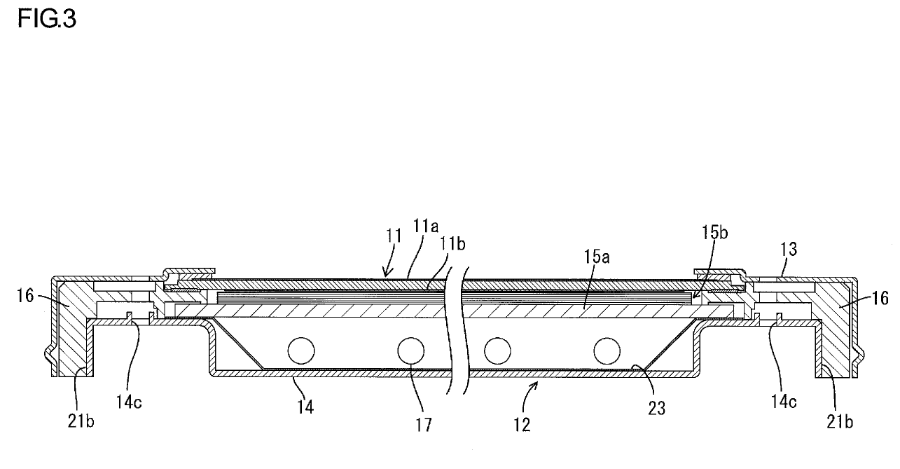

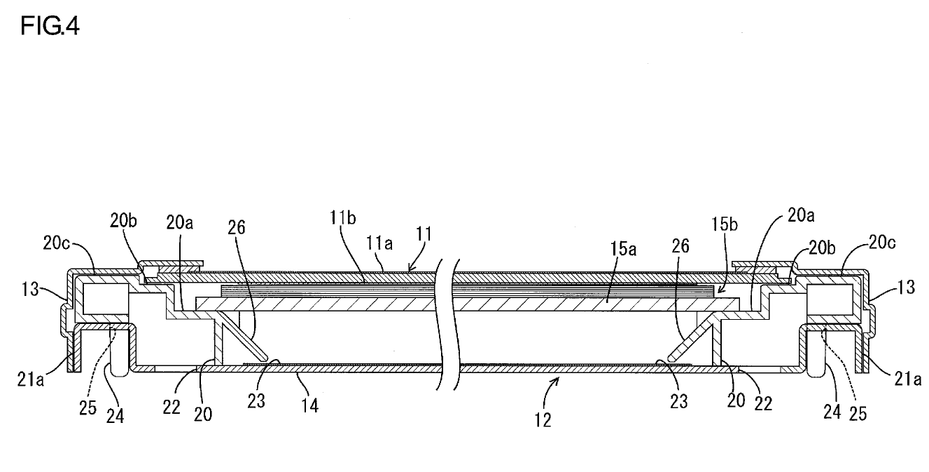

The liquid crystal panel (display panel) 11 is configured so that a pair of glass substrates is bonded to each other with a predetermined gap therebetween, and a liquid crystal is sealed between the glass substrates. On one of the glass substrates, a switching element (for example, TFT) connected to source wiring and gate wiring perpendicular to each other, a pixel electrode connected to the switching element, and further an orientation film or the like are provided. On the other of the glass substrates, a color filter in which coloring portions of such as R (red), G (green) and B (blue) are placed in a predetermined arrangement, a counter electrode, and further an orientation film or the like are provided. On outsides of the substrates, polarizing plates 11a and 11b are provided (see FIGS. 3 and 4).

As shown in FIG. 2, the backlight unit 12 includes a substantially box-shaped chassis 14 opening on a side of a light emission surface (liquid crystal panel 11), a diffuser plate 15a provided to cover an opening 14b in the chassis 14, a plurality of optical sheets 15b provided between the diffuser plate 15a and the liquid crystal panel 11, and a frame 16 that is provided along a long side of the chassis 14 and holds a long side edge part of the diffuser plate 15a between the frame 16 and the chassis 14. In the chassis 14, a cold cathode tube (light source) 17, a lamp clip 18 for mounting the cold cathode tube 17 to the chassis 14, a relay connector 19 that relays electrical connection at each edge portion of the cold cathode tube 17, and a holder 20 that collectively covers edge portions of a group of cold cathode tubes 17 and a group of relay connectors 19 are further provided. In the backlight unit 12, the side closer to the diffuser plate 15a than the cold cathode tube 17 is a light emission side. In FIGS. 2 to 4, the lamp clip 18 is not shown.

The chassis 14 is made of metal, and formed of sheet metal into a shallow substantially box shape including a rectangular bottom plate, and a folded outer edge part 21 (a folded outer edge part 21a in a short side direction and a folded outer edge part 21b in a long side direction) folded to rise from each side into a substantially U shape. In the bottom plate of the chassis 14, a plurality of mounting holes 22 in which the relay connectors 19 are mounted are provided in opposite edge portions in the long side direction. Further, in an upper surface of the folded outer edge part 21b of the chassis 14, as shown in FIG. 3, a fixing hole 14c is provided so that the bezel 13, the frame 16, and the chassis 14 or the like can be integrated by a screw or the like.

A reflective sheet 23 is provided on an inner surface side (side opposing the cold cathode tube 17) of the bottom plate of the chassis 14. The reflective sheet 23 is made of synthetic resin, has a white surface with high reflectivity, and is placed along an inside of a bottom plate surface of the chassis 14 to cover substantially the entire bottom plate surface. As shown in FIG. 3, a long side edge part of the reflective sheet 23 rises to cover the folded outer edge part 21b of the chassis 14, and is held between the chassis 14 and the diffuser plate 15a. The reflective sheet 23 can reflect a light emitted from the cold cathode tube 17 toward the diffuser plate 15a.

The cold cathode tube 17 has an elongated tubular shape, and a plurality of cold cathode tubes 17 are housed in the chassis 14 in a state where the cold cathode tubes 17 are arranged in parallel with each other and a length direction (axial direction) thereof matching the long side direction of the chassis 14 (see FIG. 2). The cold cathode tube 17 is slightly raised from the bottom plate (reflective sheet 23) of the chassis 14, each edge portions is fitted in the relay connector 19, and the holder 20 is mounted to cover the relay connectors 19.

The holder 20 is made of white synthetic resin, covers the edge portion of the cold cathode tube 17, and has an elongated substantially box shape extending along the short side direction of the chassis 14. As shown in FIG. 4, the holder 20 has a stepped surface on which the diffuser plate 15a and the liquid crystal panel 11 can be placed on different steps, is provided to partially overlap the folded outer edge part 21a in the short side direction of the chassis 14, and forms a side wall of the backlight unit 12 together with the folded outer edge part 21a. An insertion pin 24 protrudes from a surface of the holder 20 opposing the folded outer edge part 21a of the chassis 14, and the insertion pin 24 is inserted into an insertion hole 25 formed in an upper surface of the folded outer edge part 21a of the chassis 14 to mount the holder 20 to the chassis 14.

The stepped surface of the holder 20 includes three surfaces parallel to the bottom plate surface of the chassis 14, and a short side edge part of the diffuser plate 15a is placed on a first surface 20a in the lowest position. Further, a tilted cover 26 tilted toward the bottom plate surface of the chassis 14 extends from the first surface 20a. On a second surface 20b of the stepped surface of the holder 20, a short side edge part of the liquid crystal panel 11 is placed. A third surface 20c in the highest position of the stepped surface of the holder 20 is provided in a position overlapping the folded outer edge part 21a of the chassis 14, and in contact with the bezel 13.

The diffuser plate 15a is formed of a plate member made of synthetic resin in which light scattering particles are dispersed, and has a function of scatting a linear light emitted from the cold cathode tube 17 as a tubular light source. The short side edge part of the diffuser plate 15a is placed on the first surface 20a of the holder 20 as described above, and is not subjected to a vertical constraining force. A long side edge part of the diffuser plate 15a is held between the chassis 14 (reflective sheet 23) and the frame 16 and secured as shown in FIG. 3.

The optical sheet 15b provided on the diffuser plate 15a includes a diffusing sheet, a lens sheet, and a reflective polarizing plate stacked in order from the side of the diffuser plate 15a, and has a function of turning a light emitted from the cold cathode tube 17 and having passed through the diffusing plate 15a into a planer light. The liquid crystal panel 11 is provided on an upper surface of the optical sheet 15b, and the optical sheet 15b is held between the diffuser plate 15a and the liquid crystal panel 11.

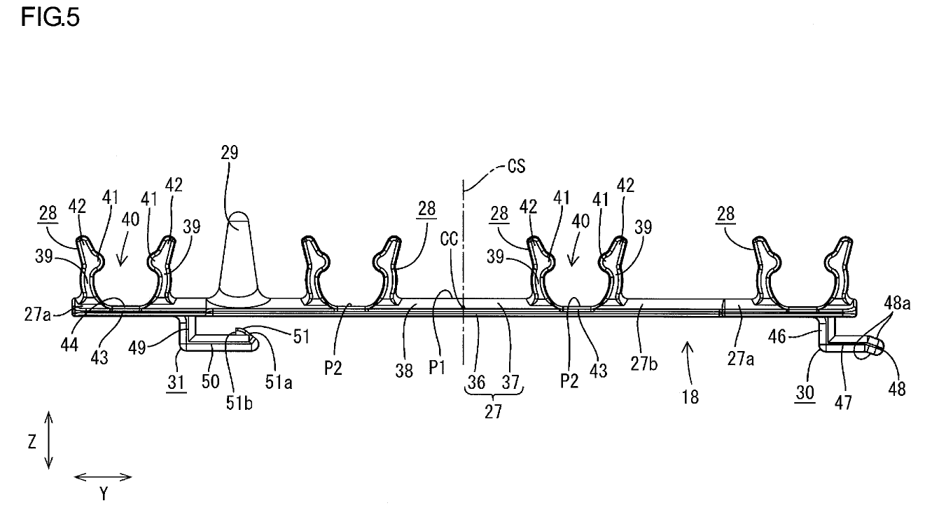

Now, the lamp clip 18 will be described in detail. The lamp clip 18 is made of synthetic resin (for example, polycarbonate), has a white surface with high light reflectivity, and includes, as shown in FIGS. 5 to 8, a main body 27 (mounting plate, base portion) having a substantially plate shape along the bottom plates of the chassis 14 and the reflective sheet 23 and a substantially rectangular shape on the plan view. The lamp clip 18 is mounted to the chassis 14 with a length direction of the main body 27 being in a position substantially parallel to the short side direction (Y-axis direction) of the chassis 14, that is, a position (direction) substantially parallel to a direction perpendicular to the axial direction (length direction, X-axis direction) of the cold cathode tube 17. Hereinafter, the long side direction and the short side direction are described with reference to the bottom plates of the chassis 14 and the reflective sheet 23 if not otherwise specified. The Z-axis direction is described with an upper side in FIGS. 3 and 4 being a front side and an opposite lower side being a back side.

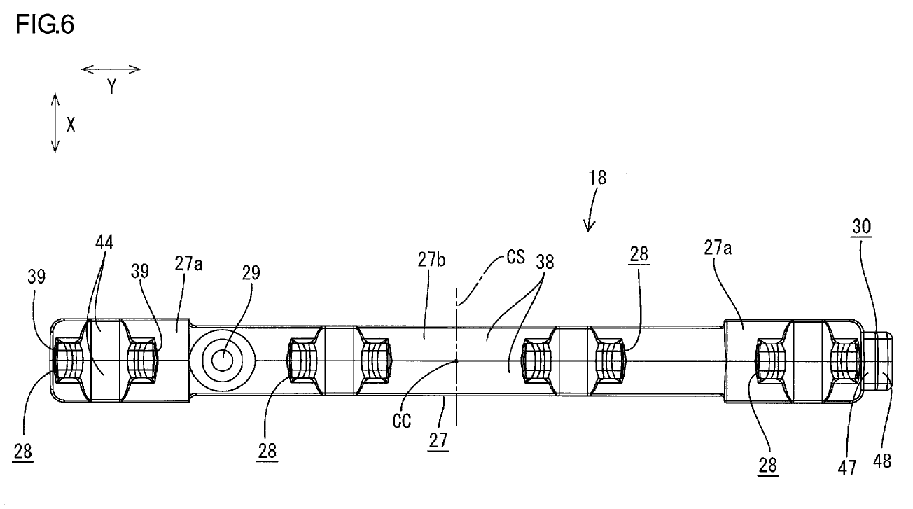

On a surface on the front side (a surface opposing the diffuser plate 15a and the cold cathode tube 17, a surface on the side opposite the chassis 14) of the main body 27, a lamp gripping portion 28 for supporting the cold cathode tube 17 in a predetermined height position, and a support pin 29 for supporting the diffuser plate 15a in a position higher than the cold cathode tube 17 are provided. A plurality of (four in this embodiment) lamp gripping portions 28 are arranged in positions spaced apart from each other in the length direction of the main body 27, and grip different cold cathode tubes 17. Pitches between the lamp gripping portions 28 are substantially the same, and match pitches between the cold cathode tubes 17 arranged in the chassis 14. A support pin 29 is placed in a position offset (displaced), that is, eccentric from a center CC of the main body (FIGS. 5 and 6). In other words, the support pin 29 is provided in a position off the center CC of the main body 27, and further in other words, in a position away from the center CC of the main body 27. Further in other words, the support pin 29 is provided in a position a predetermined distance (space) apart from the center CC of the main body 27. Further in other words, in a position between the center CC of the main body 27 and an outer peripheral edge portion. Specifically, the support pin 29 is provided in a position offset (displaced), that is, eccentric in the length direction from a surface CS passing through the center CC (middle position in the length direction) of the main body 27 and along a direction perpendicular to the Z-axis direction and the X-axis direction, that is, a direction perpendicular to the length direction of the main body 27. More Specifically, the support pin 29 is placed in a substantially intermediate position between a lamp gripping portion 28 closest to an edge of the main body 27, and a lamp gripping portion 28 adjacent to the above-described lamp gripping portion 28. On a surface on the back side (a surface opposing the chassis 14 and the reflective sheet 23, a surface on the side opposite the diffuser plate 15a and the cold cathode tube 17) of the main body 27, mounting portions 30 and 31 for holding the lamp clip 18 in a mounting state to the chassis 14 are provided. A plurality of (two in this embodiment) mounting portions 30 and 31 are provided in positions spaced apart from each other in the length direction of the main body 27.

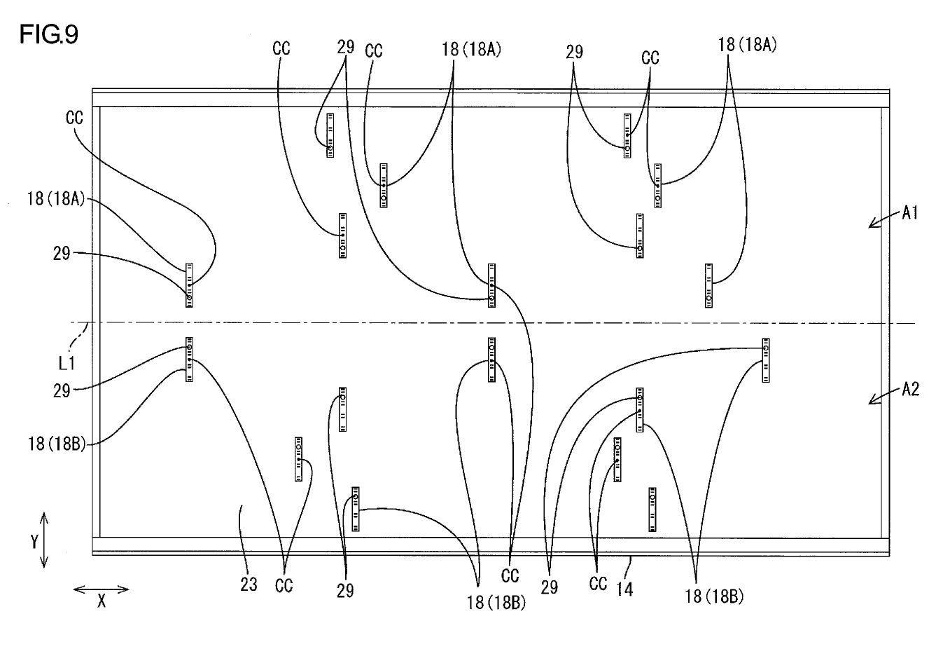

The lamp clips 18 are arranged in a plurality of dispersed positions on inner surfaces of the bottom plates of the chassis 14 and the reflective sheet 23 as shown in FIG. 9. The arrangement thereof will be described below in detail. The lamp clips 18 are arranged in a plurality of positions spaced from each other in the long side direction (X-axis direction) of the chassis 14 and the reflective sheet 23 so as to grip the cold cathode tubes 17 in a plurality of positions spaced apart in the axial direction. Further, a larger number of lamp clips 18 are provided on a middle side (side of a reference line L1) than opposite end sides in the short side direction (Y-axis direction) of the bottom plates of the chassis 14 and the reflective sheet 23. Specifically, on the middle side in the short side direction of the chassis 14 and the reflective sheet 23, more specifically, in each of positions with a virtual reference line L1 therebetween passing through the middle position and crossing along the long side direction (X-axis direction, length direction of the cold cathode tube 17, direction perpendicular to the length direction of the main body 27, and plane direction of the diffuser plate 15a), three lamp clips 18 are provided spaced apart in the long side direction, and on the opposite end sides in the short side direction from the six lamp clips 18, pairs of lamp clips 18 are provided spaced apart in the long side direction. Thus, a larger number of lamp gripping portions 28, that is, a larger number of support parts for the cold cathode tubes 17 are provided, and a larger number of support pins 29, that is, a larger number of support parts for the diffuser plate 15a are provided on the middle side (side of the reference line L1) than the opposite end sides in the short side direction of the chassis 14 and the reflective sheet 23.

The pairs of lamp clips 18 (lamp clips 18 provided on the opposite end sides with respect to the middle side in the short side direction) arranged in the long side direction are provided in positions displaced in the long side direction with respect to adjacent lamp clips 18 in the short side direction. Thus, as compared with lamp clips 18 arranged in line along the short side direction, the lamp clips 18 are dispersed in the surface of the bottom plate of the reflective sheet 23, and shadows of the lamp clips 18 are not easily visually identified from the property of human eyes. Specifically, with the same number of the lamp clips 18, the lamp clips 18 linearly or collectively arranged are easily visually identified from the property of human eyes, while the lamp clips 18 dispersed as in this embodiment reduces occurrence of luminance unevenness in the backlight unit 12 even if the reflective sheet 23 and the lamp clip 18 have different light reflectivities.

A mounting direction (mounting position, mounting state) of each lamp clip 18 to the bottom plates of the chassis 14 and the reflective sheet 23 is set so that each support pin 29 is directed toward the above-described reference line L1 (closer to the reference line L1, or near the reference line L1), that is, eccentric toward the reference line L1. Specifically, each lamp clip 18 is mounted with the length direction of the main body 27 matching the short side direction (Y-axis direction, length direction of the cold cathode tube 17, direction perpendicular to the reference line L1) of the chassis 14 and the reflective sheet 23. In each lamp clip 18, the support pin 29 is provided in the eccentric position in the length direction of the main body 27, and thus there is a direction in the mounting direction to the chassis 14. Thus, two mounting directions of each lamp clip 18 are set including a first mounting direction (first mounting position, first mounting state) with the support pin 29 directed downward in FIG. 9, and a second mounting direction (second mounting position, second mounting state) with the support pin 29 directed upward in FIG. 9 in the direction opposite the first mounting direction. On the bottom plates of the chassis 14 and the reflective sheet 23, the lamp clips 18 mounted in a first region A1 on an upper side of the reference line L1 in FIG. 9 are in the first mounting direction, while the lamp clips 18 mounted in a second region A2 on a lower side in FIG. 9 are in the second mounting direction. Specifically, the lamp clips 18 are divided into a first lamp clip group 18A in the first mounting direction and a second lamp clip group 18B in the second mounting direction at the reference line L1 (as a border), and all the support pins 29 eccentrically placed on the main body 27 are placed closer to the reference line L1. In this state, a distance between the reference line L1 and the support pin 29 of each lamp clip 18 is smaller than a distance between the reference line L1 and the center CC of the main body 27 of each lamp clip 18. Thus, each support pin 29 supports the diffuser plate 15a in a position closer to the middle side in the short side direction of the diffuser plate 15a, in other word, distribution density of the support pins 29 increases in positions closer to the middle side in the short side direction of the diffuser plate 15a. If thermal expansion or thermal contraction occurs in the diffuser plate 15a, a screen middle side tends to be bent or warped toward the cold cathode tube 17 in structure, but the larger number of support pins 29 are distributed on the screen middle side, thereby allowing bending or warpage to be satisfactorily controlled. There are an optimum (smaller) number and arrangement of the lamp clips 18 to support the cold cathode tubes 17. With the optimum predetermined arrangement, the lamp clips 18 with the support pin 29 eccentrically placed are placed so that the support pins 29 are placed closer to the reference line L1, thereby allowing bending or warpage of the diffuser plate 15a to be satisfactorily controlled.

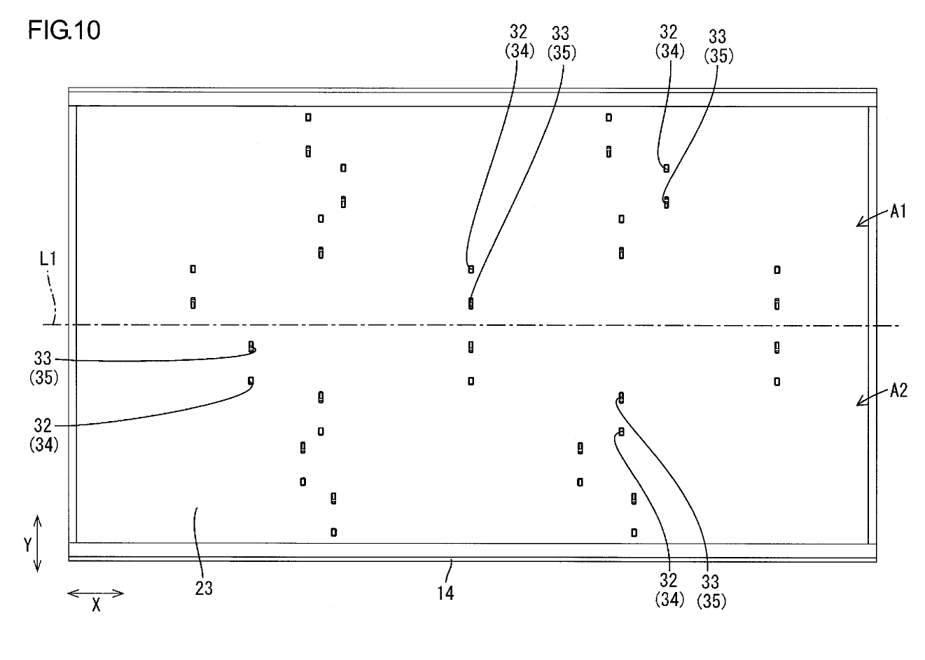

In the inner surfaces of the bottom plates of the chassis 14 and the reflective sheet 23, as shown in FIG. 10, mounting holes 32 and 33 and insertion holes 34 and 35 through which the mounting portions 30 and 31 are inserted are formed through the bottom plates in the thickness direction in positions to which the lamp clips 18 are to be mounted. The mounting portions 30 and 31, the mounting holes 32 and 33, and the insertion holes 34 and 35 will be described later in detail.

Next, detailed structures of components of the lamp clip 18 will be described. First, the main body 27 has an elongated substantially rectangular shape along the short side direction (Y-axis direction) of the chassis 14 as shown in FIGS. 5 to 8, and an intermediate portion is formed to be slightly narrower than opposite edge portions in the length direction. Thus, a surface area of the main body 27 is smaller than that in a case that a main body 27 has a fixed width matching a width of a wide portion 27a over the entire length, and a ratio of a surface area of all the lamp clips 18 to a surface area of the entire reflective sheet 23 is small. This reduces occurrence of luminance unevenness in the backlight unit 12 even if the reflective sheet 23 and the lamp clip 18 have different light reflectivities. In the wide portions 27a (wide first part) at the opposite ends in the main body 27, a pair of lamp gripping portions 28 at opposite ends and the mounting portions 30 and 31 are provided, while in an intermediate narrow portion 27b (narrow second part), a pair of lamp gripping portions 28 closer to the middle and the support pin 29 are provided. The opposite wide portions 27a in the main body 27 have higher rigidity than the narrow portion 27b, and the mounting portions 30 and 31 are provided in the wide portions 27a. This reduces damage to the mounting portions 30 and 31 or the main body 27 even if the mounting portions 30 and 31 interfere with peripheral surfaces of the mounting holes 32 and 33 in the chassis 14 in mounting the lamp clip 18.

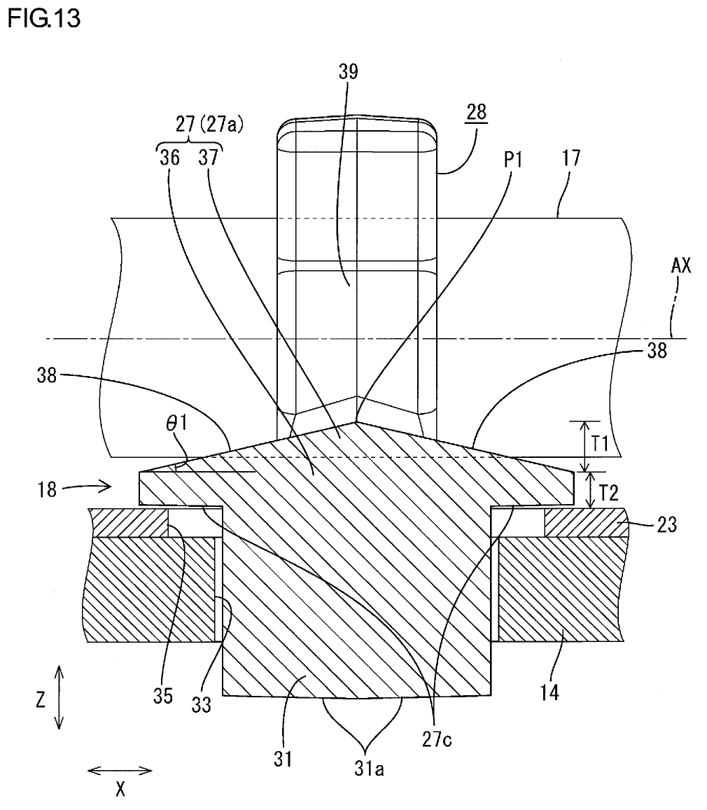

Next, a sectional shape of the main body 27 cut along a thickness direction will be described. As shown in FIG. 13, the main body 27 includes a base 36 having a mounting surface (opposing surface) to the bottom plates of the chassis 14 and the reflective sheet 23, and a raised portion 37 protruding from the base 36 toward the front side (toward the cold cathode tube 17 and the diffuser plate 15a) and having a sloped surface 38 on a surface thereof.

The base 36 has a substantially rectangular shape (block shape) with a substantially even thickness (height, size in the Z-axis direction) and a substantially fixed width (size in the X-axis direction) and an elongated sectional shape. The raised portion 37 has, on a protruding base end side, substantially the same width as the base 36, but has a shape that gradually decreases in width (size in the short side direction or an X-axis direction of the body 27) toward a vertex. In other words, the raised portion 37 has an angular shape with the largest thickness in a middle position (vertex P1) in the width direction (X-axis direction) and a progressively decreasing thickness from the middle portion toward opposite end positions (opposite skirt sides) in the width direction. Further in other words, the raised portion 37 has a hill-like shape slops away from a central axis AX of the cold cathode tube 17. Thus, opposite edge portions (outer rim on the long side) in the width direction along the length direction of the raised portion 37 are thinner over the entire region than the middle side. Namely, a smooth transition is provided between the raised portion 37 and the base 36.

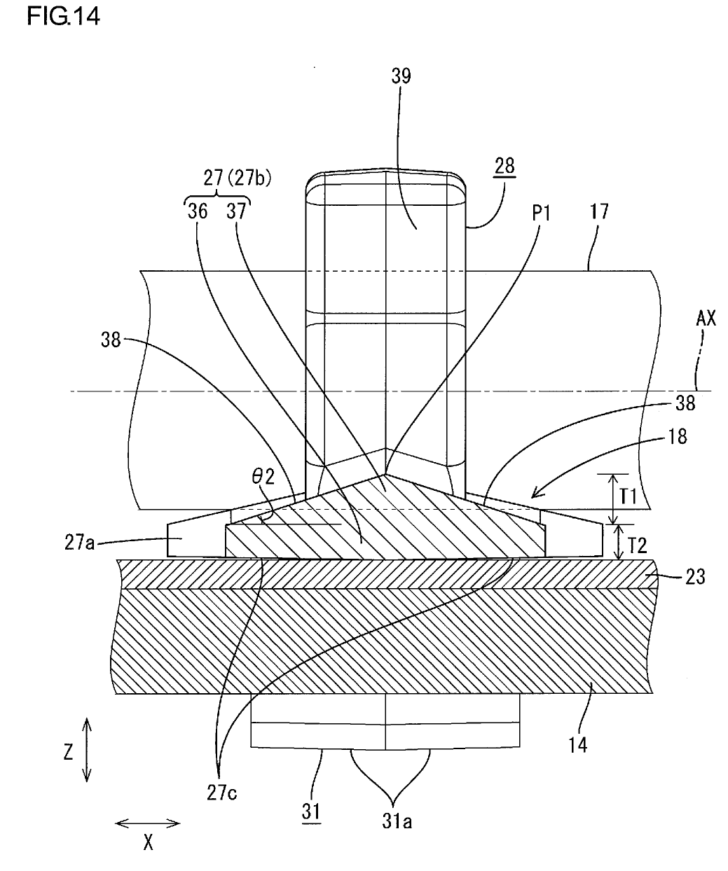

On the surface of the raised portion 37, a pair of sloped surfaces 38 sloping downward from the middle position to the opposite end positions in the width direction are integrally formed. The sloped surface 38 slopes so that a distance from the reflective sheet 23 progressively decreases from the middle position toward the opposite end positions in the width direction of the raised portion 37, in other words, a distance from the diffuser plate 15a (cold cathode tube 17) progressively increases. Specifically, the raised portion 37 has a substantially isosceles triangular sectional shape, and has the pair of sloped surface 38 formed on the surface at the vertex P1 in the middle in the width direction as a border. Specifically, the raised portion 37 has a symmetrical shape with respect to an axis of symmetry along the Z-axis direction passing through the middle position in the width direction. Thus, the sloped surfaces 38 have the same slope angle. An angle formed by the sloped surfaces 38 connected at the vertex P1 of the raised portion 37 is an obtuse angle. A thickness T1 at the vertex P1 of the raised portion 37 is set to be larger than a thickness T2 of the base 36. As shown in FIGS. 13 and 14, the wide portions 27a at the opposite ends in the length direction of the main body 27 and the narrow portion 27b as the intermediate portion therebetween have different slope angles of the sloped surface 38 in the raised portion 37, and a slope angle θ1 in the wide portion 27a is smaller (more gentle) than a slope angle θ2 in the narrow portion 27b. Also in a bottom surface (surface of the main body 27 opposing the chassis 14 and the reflective sheet 23) of the base 36, a pair of sloped surfaces 27c having a more gentle slope angle than the sloped surface 38 with a vertex in the middle position in the width direction is formed over the entire length.

As described above, the raised portion 37 having the sloped surfaces 38 is formed on the main body 27, and thus the sloped surfaces 38 can satisfactorily reflect the light emitted from the cold cathode tube 17 toward the diffuser plate 15a. Also, the entire opposite edge portions in the width direction along the length direction of the raised portion 37 are thinner than the middle portion and there is little step from the base 36, and thus there is few shadow portions in the raised portion 37. This can provide uniform light reflective efficiency of the surface of the main body 27 as much as possible, and thus reduce occurrence of a dark portion (shadow portion, shaded portion) in the main body 27 as much as possible. The base 36 is provided on a back side of the raised portion 37, but the thickness T2 thereof is set to be smaller than the largest thickness T1 (thickness T1 at the vertex P1) of the raised portion 37, and also the sloped surfaces 38 of the raised portion 37 provide uniform light reflective efficiency, and thus opposite side surfaces in the width direction of the base 36 are not easily visually identified as dark portions. The sloped surfaces 38 without a curve are formed in the surface of the raised portion 37, and thus dimensional accuracy of the raised portion 37 can be easily obtained in producing the lamp clip 18 by resin molding.

The raised portion 37 has a certain thickness in the middle portion in the width direction, but is extremely thin at the opposite edge portions in the width direction, and a light may pass through the thin portions. However, the base 36 is provided on the back side of the raised portion 37, and has a thickness sufficient for blocking the light, thereby avoiding the light from passing through the opposite edge portions in the width direction of the main body 27. Thus, even if the chassis 14 is provided on the back side of the opposite edge portions in the width direction of the main body 27 without the reflective sheet 23, the chassis 14 (and the mounting holes 32 and 33) is less likely to be recognized as a dark portion from the front side. With the thin opposite edge portions in the width direction of the raised portion 37, the main body 27 may have insufficient strength, but the base 36 is provided on the back side of the raised portion 37, thereby ensuring sufficient strength and rigidity of the main body 27.

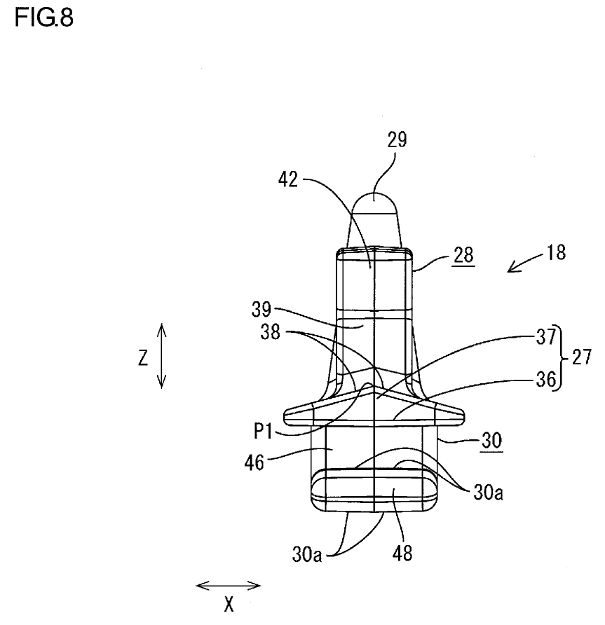

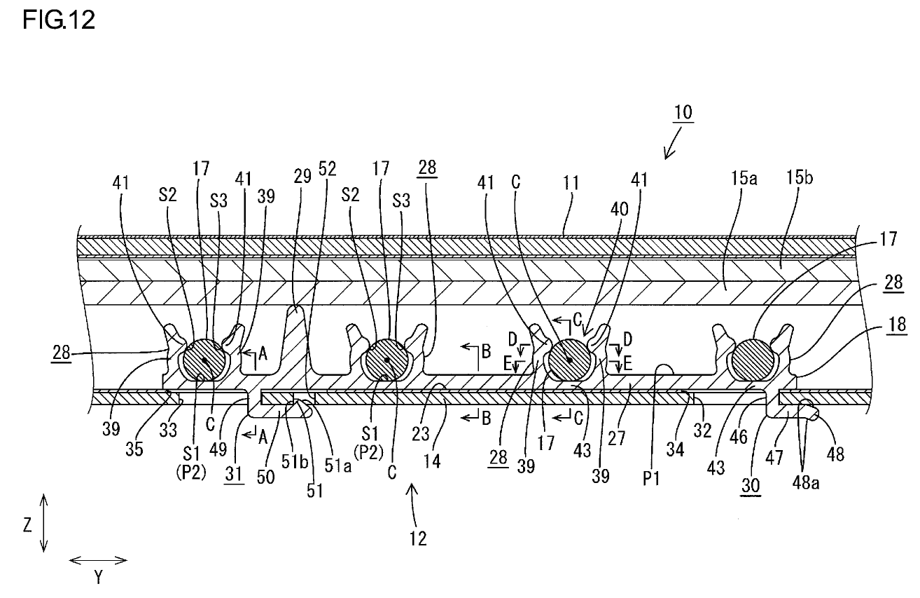

Next, the support pin 29 that constitutes a support structure for the diffuser plate 15a will be described in detail. As shown in FIG. 12, the support pin 29 supports, from a back side, a screen middle portion rather than an outer rim supported by the holder 20 or the like in the diffuser plate 15a to restrict the diffuser plate 15a from being bent or warped toward the cold cathode tube 17. As shown in FIG. 6, the support pin 29 has a circular sectional shape when cut along a horizontal direction, and is tapered such that the diameter thereof gradually decreases from a proximal end toward a tip as shown in FIGS. 5 and 8. Specifically, the support pin 29 has a substantially conical shape. A tip portion of the support pin 29 that can abut against the diffuser plate 15a has a rounded surface. In an outer peripheral surface of a proximal end portion of the support pin 29, a curved surface extending toward the main body 27 is formed and gently connected to the sloped surfaces 38 of the main body 27 without a step. The diameter of the proximal end portion of the support pin 29 is larger than a width (size in the X-axis direction) of an arm portion 39 of the lamp gripping portion 28 described next, while the diameter of the tip portion is smaller than the width of the arm portion 39 of the lamp gripping portion 28. A protruding height of the support pin 29 from the main body 27 is set to be higher than that of the lamp gripping portion 28. As described above, the support pin 29 is placed in the position eccentric from the middle position in the length direction of the main body 27, but placed in the middle position in the width direction.

The support pin 29 protrudes to the highest position in the lamp clip 18. Thus, when the lamp clip 18 is attached to and detached from the chassis 14, an operator can grip the support pin 29 and perform the operation, and the support pin 29 also functions as a console in attachment and detachment.

Next, the lamp gripping portion 28 that constitutes the support structure for the cold cathode tube 17 will be described in detail. As shown in FIG. 12, the lamp gripping portion 28 can support an intermediate portion between the opposite edge portions provided with electrodes in the cold cathode tube 17, that is, a light emitting portion from a back side in a height position slightly raised from the reflective sheet 23. The lamp gripping portion 28 has an open-end ring-like shape that opens toward the front. The lamp gripping portion includes a pair of arm portions 39 that face each other. Between ends of the arm portions 39, an opening 40 that allows the cold cathode tube 17 to pass through is provided. The cold cathode tube 17 is attached to or detached from the lamp gripping portion 28 along the Z-axis direction (thickness direction of the bottom plates of the chassis 14 and the reflective sheet 23). The arm portions 39 have a cantilever shape rising from the front side surface of the main body 27 at locations apart from each other in the length direction (Y-axis direction). The arm portions 39 are curved into a substantially arc shape. A curvature of each arm portion 39 substantially matches a curvature of the outer peripheral surface of the cold cathode tube 17 to be mounted. When the cold cathode tube 17 is mounted, a gap is present between the arm portions 39 and the cold cathode tube 17. The gap has a substantially fixed width in a circumferential direction. The arm portions 39 have a symmetrical shape with respect to an axis of symmetry along the Z-axis direction passing through the middle position in the Y-axis direction of the lamp gripping portion 28. The arm portions 39 are elastically deformable in the width direction with a rising base end from the main body 27 as a pivot. Each arm portion 39 has a symmetrical shape with respect to an axis of symmetry along the Z-axis direction passing through the center position in the width direction (X-axis direction) as shown in FIG. 8. The arm portion 39 has a width smaller than the width of the main body 27. The arm portion 39 gradually increases the width around a protruding base end and is gently connected to the main body 27. Therefore, a smooth transition is provided between the arm portion 39 and the main body 27.

As shown in FIG. 12, holding protrusions 41 protrude from inner surfaces (inner surfaces that face the cold cathode tube 17) of the arm portions 39 around the distal ends thereof for retaining the cold cathode tube 17 in place. The above-described opening 40 is located between the holding protrusions 41. A width of in the opening 40 is defined slightly narrower than the outer diameter of the cold cathode tube 17. Thus, when the cold cathode tube 17 is attached and detached through the opening 40, the arm portions 39 are pushed outward by the cold cathode tube 17. Namely, the arm portions 39 are elastically deformed and the opening 40 expands. The holding protrusion 41 protrudes inward from the inner surface of the distal ends of the arm portion 39 (toward the central axis AX of the cold cathode tube 17), and is located on the front side (light output side) of the center C of the cold cathode tube 17 when the cold cathode tube 17 is mounted. Namely, the holding protrusions 41 is located on a side to which the cold cathode tube 17 is pulled during the removal. In the mounting state, the cold cathode tube 17 is supported at three points by a middle first support point S1 located directly below the center C of the cold cathode tube 17, a second support point S2 and a third support point S3 at inner ends of the holding protrusions 41 on the bottom surface of the lamp gripping portion 28. Between the adjacent ones of the support points S1 to S3, a slight gap (clearance) extending circumferentially is present between the outer peripheral surface of the cold cathode tube 17 and the inner peripheral surface of the lamp gripping portion 28. Lines connecting the support points S1 to S3 form an isosceles triangle. Angles formed by any two of the line connecting the first support point S1 and the center C of the cold cathode tube 17, the line connecting the second support point S2 and the center C, and the line connecting the third support point S3 and the center C (these lines are not shown) are obtuse.

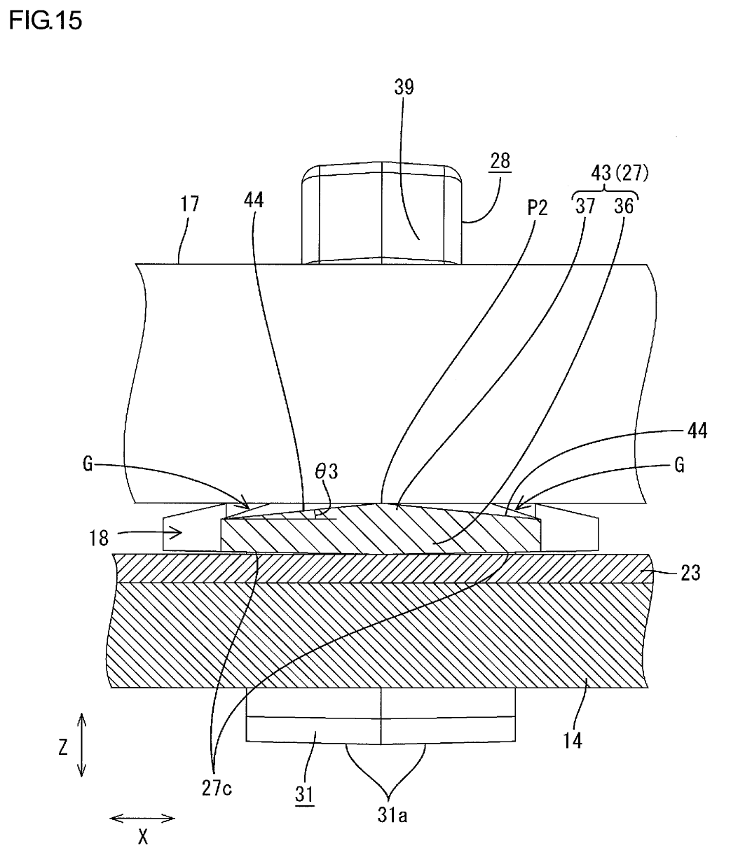

On outer surfaces of the distal ends of the arm portions 39, guide portions 42 (FIG. 15) for guiding the mounting operation of the cold cathode tube 17 are provided. The guide portions 42 are tapered to rise obliquely outward from the arm portions 39. The guide portions 42 slope from protruding base ends toward protruding tips to be spaced apart from each other, and inner surfaces opposing the cold cathode tube 17 are sloped surfaces similarly sloping. Thus, the space between the inner surfaces that are opposing surfaces of the guide portions 42 gradually decreases toward the lower side in the drawing, that is, toward the mounting direction of the cold cathode tube 17, while gradually increases toward the removing direction of the cold cathode tube 17. Thus, the inner surfaces of the guide portions 42 can smoothly guide the mounting operation of the cold cathode tube 17. The inner surfaces of the guide portions 42 are gently connected to the inner surfaces of the holding protrusions 41.

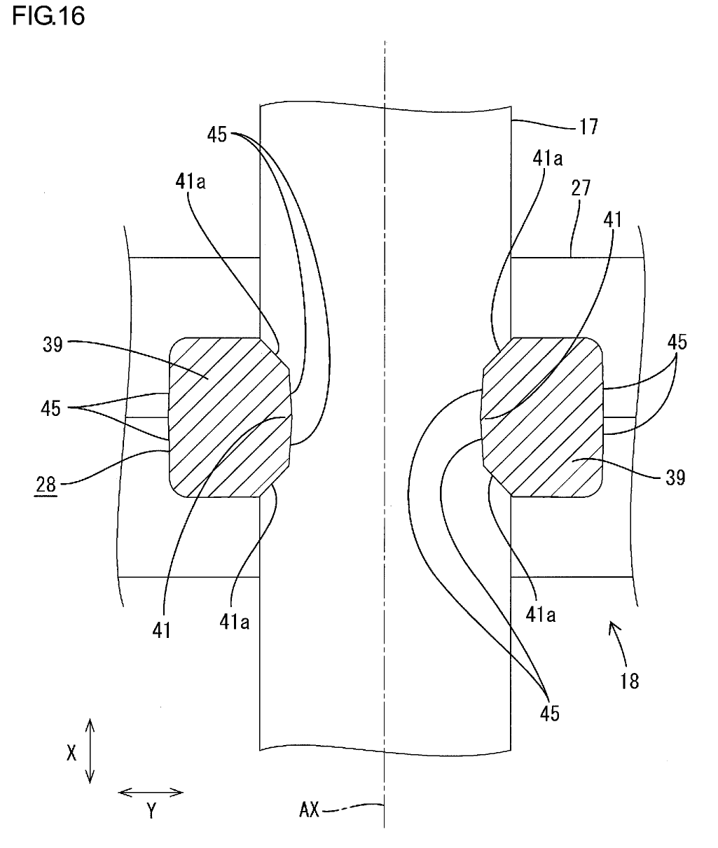

As shown in FIG. 16, each holding protrusion 41 that is a part of the lamp gripping portion 28 has a tapered shape. The width (size that measures in the X-axis direction) of the holding protrusion 41 gradually decreases from outside to inside, that is, it gradually decreases toward the cold cathode tube 17. Specifically, the width, that is, a size that measures in the length direction of the cold cathode tube 17 is the largest at an outer end where a distance to the central axis AX of the cold cathode tube 17 is the largest. The width is the smallest at an inner end where a distance to the central axis AX is the smallest. The width is gradually decreases toward the central axis AX. Specifically, the width is proportional to the distance to the central axis AX in a mounting state. Thus, a pair of tapered surfaces (sloped surfaces) 41a having the same slope angle is formed on side surfaces of the holding protrusion 41 at ends in a width direction. The holding protrusion 41 covers the cold cathode tube 17 from the front side (light output side) in the lamp gripping portion 28 and has a tapered shape as viewed from the front side.

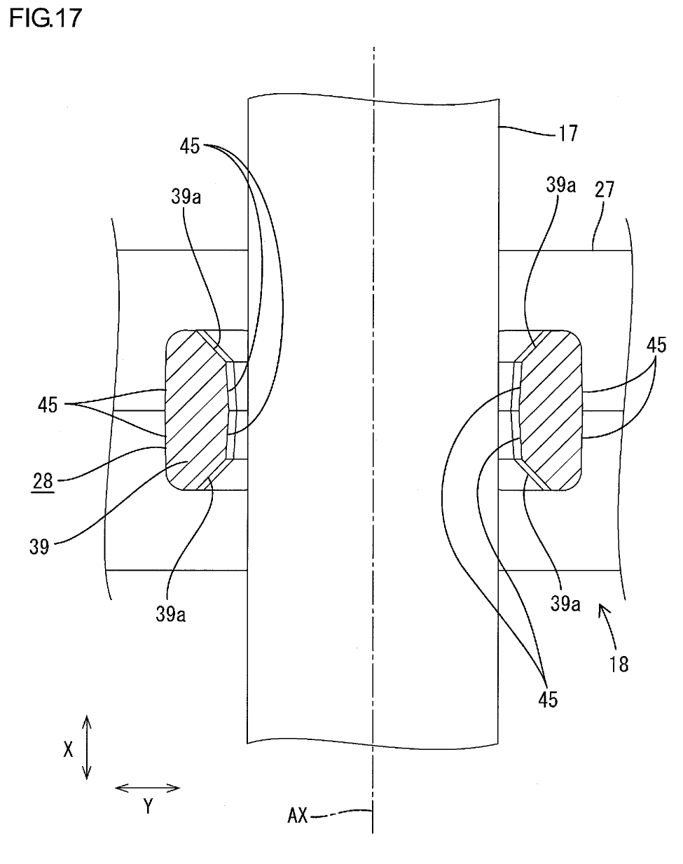

As shown in FIG. 17, each arm portion 39 also has a tapered shape that matches the shape of the holding protrusion 41. It also has an extended tapered surface 39a continuous to the holding protrusion 41 at either end in the width direction. Therefore, a smooth transition is provided between the arm portion 39 and the holding protrusion 41. The extended tapered surface 39a is formed over the entire length of the arm portion 39 from a distal end portion adjacent to the holding protrusion 41 to a proximal end portion. The arm portion 39 gradually decreases in width from the outer end position to the inner end position over the entire length. Namely, the extended tapered surface 39a is formed in a portion on the front side of the arm portion 39 with respect to the center C of the cold cathode tube 17. The guide portion 42 is tapered similarly to the holding protrusion 41 and the arm portion 39. When the lamp gripping portion 28 is generally viewed, an inner edge portion of the holding protrusion 41 closest to the central axis AX of the cold cathode tube 17 is formed to be narrowest.

With the cold cathode tube 17 being mounted, as shown in FIG. 16, the holding protrusion 41 of the lamp gripping portion 28 covers the front side (light output side) of the cold cathode tube 17 and forms a shadow, in other words, the holding protrusion 41 is interposed between the cold cathode tube 17 and the diffuser plate 15a. The holding protrusion 41 is tapered as described above, and a covered area of the cold cathode tube 17 on the front side is smaller than an area covered by the holding protrusion 41 having a fixed width. This means that an effective lighting area by the cold cathode tube 17 increases and thus an amount of light provided by the cold cathode tube 17. Besides the holding protrusion 41, the arm portion 39 and the guide portion 42 are tapered over the entire length, and thus an area of the outer peripheral surface of the cold cathode tube 17 covered by the arm portion 39, the holding protrusion 41, and the guide portion 42 is reduced as much as possible. This further contributes to increasing the amount of light. A lamp gripping portion simply formed to be narrow may provide insufficient strength, but in this embodiment, the outer edge portion of the lamp gripping portion 28 ensures an original width, thereby ensuring sufficient strength. The tapered surfaces 41a and the extended tapered surface 39a without curves are formed on the surfaces of the arm portion 39, the holding protrusion 41, and the guide portion 42, and thus dimensional accuracy of the lamp gripping portion 28 can be easily obtained in producing the lamp clip 18 by resin molding.

As shown in FIGS. 5 and 12, the bottom surface (including the first support point S1) of the lamp gripping portion 28 between the arm portions 39 is located to be lower than the vertex P1 of the sloped surfaces 38 (the vertex of the raised portion 37) of the main body 27. In other words, a recess having a predetermined width is formed in the front side surface of the main body 27, and the pair of arm portions 39 rises from positions on opposite sides of the recess to form the lamp gripping portion 28. The recess is formed over the entire width direction (X-axis direction) of the main body 27, and a depth thereof is slightly smaller than the largest thickness of the raised portion 37. The base 36 has an even thickness over the entire length while the raised portion 37 has a small thickness in areas corresponding to lamp gripping portions 28 in the length direction. A bottom portion 43 having the bottom surface of the lamp gripping portion 28 includes the base 36 and the areas of the raised portion 37 having the small thickness (see FIG. 15). The bottom portion 43 that is also a part of the main body 27 is wider than the arm portion 39 that is a part of the lamp gripping portion 28. The cold cathode tube 17 is supported such that the bottom surface is located in a position lower than the vertex P1 of the main body 27, that is, a position close to the reflective sheet 23 (position far from the diffuser plate 15a). This configuration contributes to reducing the thickness of the entire backlight unit 12. The center C of the cold cathode tube 17 is located in a position higher than the vertexes P1 and P2 of the main body 27 (position on the front side). The bottom surface of the lamp gripping portion 27 herein is a portion located in the lowest side in the Z-axis direction as a vertical direction in the peripheral surface of the lamp gripping portion 27 opposing the cold cathode tube 17, and also a portion closest to the chassis 14 in the peripheral surface of the lamp gripping portion 27 opposing the cold cathode tube 17. Further in other words, the bottom surface of the lamp gripping portion 27 is a proximal end portion of the lamp gripping portion 27 in the peripheral surface opposing the cold cathode tube 17.

The bottom portion of the lamp gripping portion 28 is substantially flat with a fixed height in the length direction (Y-axis direction) of the main body 27. As shown in FIG. 15, the bottom portion has a shape with an angle cross-section spread toward the bottom away from the central axis AX of the cold cathode tube 17 in the width direction (X-axis direction, length direction of the cold cathode tube 17, or the central axis AX direction) of the main body 27. Specifically, a gap G having different widths from point to point in the length direction of the cold cathode tube 17 is formed between the surface of the cold cathode tube 17 and the inner peripheral surface of the lamp gripping portion 28. More specifically, the bottom portion 43 of the lamp gripping portion 28 has an angular shape, the thickness of which is the largest in the middle position in the width direction of the main body 27 and gradually decreases from the middle position toward to the sides. The bottom surface of the lamp gripping portion 28 is constituted by a pair of sloped surfaces 44 (relief surfaces) sloping downward from the middle side toward the sides in the width direction of the main body 27. The sloped surface 44 is a sloped surface such that a distance from the reflective sheet 23 gradually decreases from the middle position toward the sides in the width direction of the main body 27. In other words, a distance (space, clearance, gap G) from the cold cathode tube 17 (diffuser plate 15a) gradually increases. In other words, the gap G between the surface of the cold cathode tube 17 and the sloped surface 44 of the lamp gripping portion 28 gradually expands from the middle of the lamp gripping portion 28 toward the sides along the length direction of the cold cathode tube 17. Namely, the largest gaps are provided at the edge of the sloped surface 44. Specifically, the raised portion 37 on the bottom portion 43 of the lamp gripping portion 28 has a substantially isosceles triangular sectional shape, and the pair of sloped surfaces 44 are formed on the bottom surface that is the surface of the raised portion 37 at the vertex P2 (including the first support point S1) in the middle in the width direction as a border. Specifically, the bottom portion 43 of the lamp gripping portion 28 has a symmetrical shape with respect to the Z-axis direction passing through the middle position in the width direction. Thus, the sloped surfaces 44 have the same slope angle θ3. An angle formed by the sloped surfaces 44 connected at the vertex P2 of the bottom portion 43 of the lamp gripping portion 28 is an obtuse angle. The vertex P2 of the bottom portion 43 of the lamp gripping portion 28 is lower than the vertex P1 of the raised portion 37 of the main body 27 as described above. Thus, the slope angle θ3 of the sloped surface 44 formed on the bottom portion 43 of the lamp gripping portion 28 is smaller than slope angles θ1 and θ2 (see FIGS. 13 and 14) of the sloped surface 38 formed on the raised portion 37 of the main body 27 outside the lamp gripping portion 28.

As shown in FIG. 17, the sloped surface 44 formed on the bottom portion 43 of the lamp gripping portion 28 is formed to continuously extend to the inner peripheral surface of the arm portion 39 to form an extended sloped surface 45. Further, as shown in FIG. 16, the extended sloped surface 45 is extended from the inner peripheral surface of the holding protrusion 41 to the inner peripheral surface and the outer peripheral surface of the guide portion 42, and further extended to the outer peripheral surface of the arm portion 39. Thus, the extended sloped surface 45 is formed over the entire area of the inner peripheral surfaces and outer peripheral surfaces of the arm portion 39, the holding protrusion 41, and the guide portion 42. Thus, the thicknesses of the arm portion 39, the holding protrusion 41 and the guide portion 42 gradually decrease from the middle position toward the sides in the width direction (X-axis direction).

In the state where the cold cathode tube 17 is mounted, as shown in FIGS. 15 to 17, the distance (space, gap) between the outer peripheral surface of the cold cathode tube 17 and the inner peripheral surface (surface opposing the cold cathode tube 17) of the lamp gripping portion 28 including the bottom surface gradually increases from the middle position toward the sides (outward in the axial direction of the cold cathode tube 17) in the X-axis direction of the lamp gripping portion 28. When the cold cathode tube 17 is lit, the light emitted from the cold cathode tube 17 that passes through the gap (clearance) present between the cold cathode tube 17 and the lamp gripping portion 28 is reflected off the sloped surface 44 and the extended sloped surface 45. It then travels toward the diffuser plate 15a. The amount of light traveling toward the diffuser plate 15a can be increased to improve light taking efficiency from the cold cathode tube 17 as compared with a case where if the lamp gripping portion 28 has a straight inner peripheral surface, it is highly likely that the light emitted from the cold cathode tube 17 is incident on the inner peripheral surface of the lamp gripping portion 28 and is reflected, and then returned as it is to the cold cathode tube 17. The extended sloped surface 45 is also formed on the outer peripheral surface of the lamp gripping portion 28, and thus a light incident on the lamp gripping portion 28 from outside can be satisfactorily reflected toward the diffuser plate 15a. This can provide uniform light reflection efficiency of the lamp gripping portion 28. The sloped surface 44 and the extended sloped surface 45 are formed on the inner and outer peripheral surfaces of the lamp gripping portion 28, which is advantageous in mold opening in resin molding of the lamp clip 18.

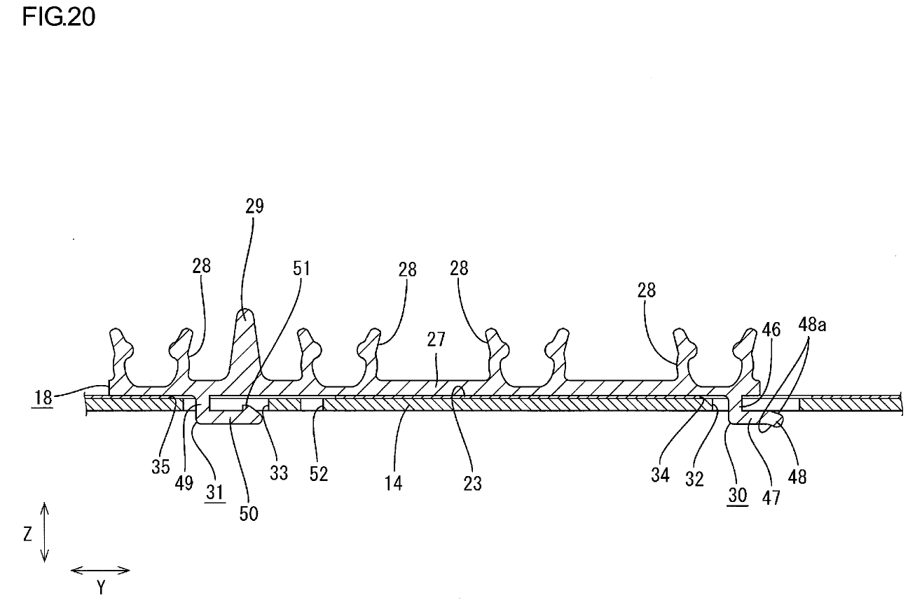

Next, the mounting portions 30 and 31 that constitute a holding structure for the lamp clip 18 on the chassis 14 will be described in detail together with the mounting holes 32 and 33 and the insertion holes 34 and 35 in the chassis 14 and the reflective sheet 23. First, the holding structure will be briefly described. As shown in FIG. 5, each of the mounting portions 30 and 31 has a hook shape along a back surface (plate surface) of the main body 27. The mounting portions 30 and 31 are inserted into the mounting holes 32 and 33 and the insertion holes 34 and 35 in the chassis 14 and the reflective sheet 23 so as to project from the back side of the chassis 14 (see FIG. 20). In this state, the lamp clip 18 is slid along the length direction (Y-axis direction, plate surface direction of the bottom plates of the reflective sheet 23 and the chassis 14) of the main body 27. As shown in FIG. 12, the chassis 14 and the reflective sheet 23 are held between the mounting portions 30 and 31 and the main body 27.

As described above, the pair of mounting portions 30 and 31 are provided in the positions spaced apart from each other in the length direction of the main body 27 in the lamp clip 18, and are referred to as the first mounting portion 30 and the second mounting portion 31. The first mounting portion 30 is provided on a side closer to a near edge of the main body 27 than the support pin 29. The second mounting portion 31 is provided on a side closer to a farther edge of the main body 27 from the first mounting portion 31, that is, on the same side with the support pin with respect to the first mounting portion 31. In the first mounting portion 30 and the second mounting portion 31, a pair of gentle sloped surfaces 30a and a pair of gentle sloped surfaces 31a, respectively, are formed with a vertex in a middle position in the width direction over the entire circumference and entire region. Slope angles of the sloped surfaces 30a and 31a are substantially the same as that of the sloped surface 27c on the bottom surface of the main body 27 described above.

Specifically, the first mounting portion 30 includes a base portion 46 protruding from a back side surface of the main body 27 toward the back side (side of the chassis 14 along the Z-axis direction), and a piece 47 substantially squarely bent from the tip of the base portion 46 and protruding (extending) along the length direction (Y-axis direction) of the main body 27, and has a substantially L shape as viewed from the front. The base portion 46 is located on the back side of the lamp gripping portion 28 provided at the edge portion on the side opposite the support pin 29 in the length direction of the main body 27, and more specifically, located in substantially the same position as the base end position of the arm portion 39 on the end side that constitutes the lamp gripping portion 28. The base portion 46 is connected to the wide portion 27a of the main body 27, and thus even if a force is applied to the main body 27 via the first mounting portion, the main body 27 is less likely to be deformed or damaged. The base portion 46 is provided in the substantially middle position in the width direction of the main body 27.

The piece 47 is cantilevered to extend from the base portion 46 to the side opposite the support pin 29, and has a length such that a tip portion protrudes further laterally from the edge portion (front edge portion in a sliding direction) on the side opposite the support pin 29 of the main body 27. In other words, the tip portion (including a guide portion 48 described next) of the piece 47 protrudes outward from an outer peripheral end of the main body 27 on the plan view. The piece 47 has a rectangular shape as viewed from the back side, and has a size along the X-axis direction (width) set to be smaller than a size (length) along the Y-axis direction (sliding direction). In the piece 47, a portion connected to the base portion 46 extends substantially in parallel with the main body 27, while the protruding tip portion is bent to form an obtuse angle, and the bent protruding tip portion is the guide portion 48 that can guide the mounting operation to the chassis 14. The guide portion 48 is sloped so that a distance from the main body 27 progressively increases toward the tip. In other words, the guide portion 48 is formed to be away from the main body 27 toward the tip, and has a substantially fixed thickness over the entire length, and thus both front and back surfaces thereof form guide surfaces 48a. A proximal end position of the guide portion 48 is located outside the end surface in the length direction of the main body 27. The base portion 46 and the piece 47 have substantially the same width, which is smaller than the width of the main body 27.

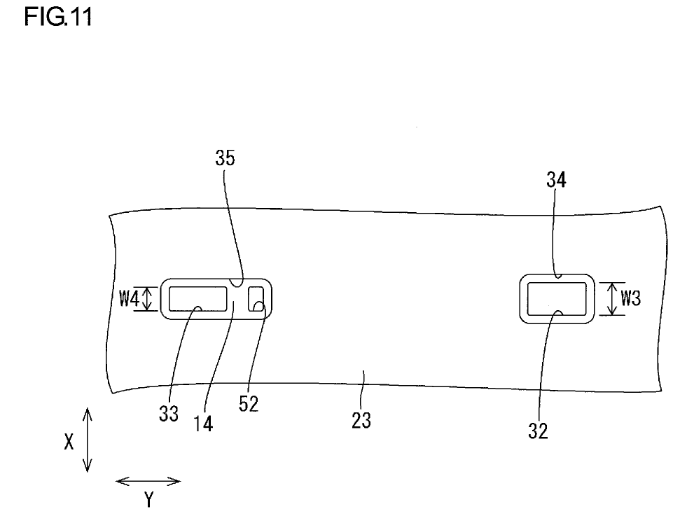

As shown in FIG. 11, the first mounting hole 32 and the first insertion hole 34 through which the first mounting portion 30 having the above-described configuration can be inserted are formed through the chassis 14 and the reflective sheet 23 in the thickness direction. The first mounting hole 32 formed in the chassis 14 has a rectangular shape on the plan view, and has a width and a length (size in a direction perpendicular to the Z-axis direction (inserting direction of the first mounting portion 30 into the first mounting hole 32) substantially the same as or larger than those of the first mounting portion 30. Meanwhile, the first insertion hole 34 formed in the reflective sheet 23 has a rectangular shape on the plan view like the first mounting hole 32, and has a width and a length much larger than those of the first mounting hole 32. A difference in size between the first mounting hole 32 and the first insertion hole 34 is the same as or larger than an assumed maximum value of a displacement amount that may occur between the reflective sheet 23 and the chassis 14 when the reflective sheet 23 is assembled to the chassis 14. Thus, the first mounting hole 32 is always present inside the first insertion hole 34 and the first mounting hole 32 is not covered by the reflective sheet 23. Conversely, the rim of the first mounting hole 32 in the chassis 14 is not covered by the reflective sheet 23 and directly faces the back surface of the main body 27 without having the reflective sheet 23 therebetween.

As shown in FIG. 20, the first mounting portion 30 is inserted into the first insertion hole 34 and the first mounting hole 32 and project from the back side of the chassis 14. The main body 27 is slid in a protruding direction (to the right in FIG. 20 along the Y-axis direction) of the piece 47. As a result, as shown in FIG. 12, the piece 47 is positioned at the front side in the sliding direction (mounting direction) around the rim of the first mounting hole 32 on the back side of the chassis 14. Thus, the reflective sheet 23 and the chassis 14 are sandwiched between the edge portion of the long side of the main body 27 and the piece 47 of the first mounting portion 30. Areas of the reflective sheet 23 and the chassis 14 sandwiched between the main body 27 and the first mounting portion 30 are rims of the first mounting hole 32 and the first insertion hole 34 on the side opposite a locking hole 52 described next. The first insertion hole 34 has a width smaller than the width of the main body 27, and also a distance from a lateral end surface of the support pin 29 in the rear end position in the sliding direction of the main body 27 to the base portion 46 is larger than a sliding amount in mounting. Thus, in the mounting state, the first mounting hole 32 and the first insertion hole 34 are covered (blocked) by the main body 27 to restrict the holes 32 and 34 from being exposed to the outside of the main body 27.

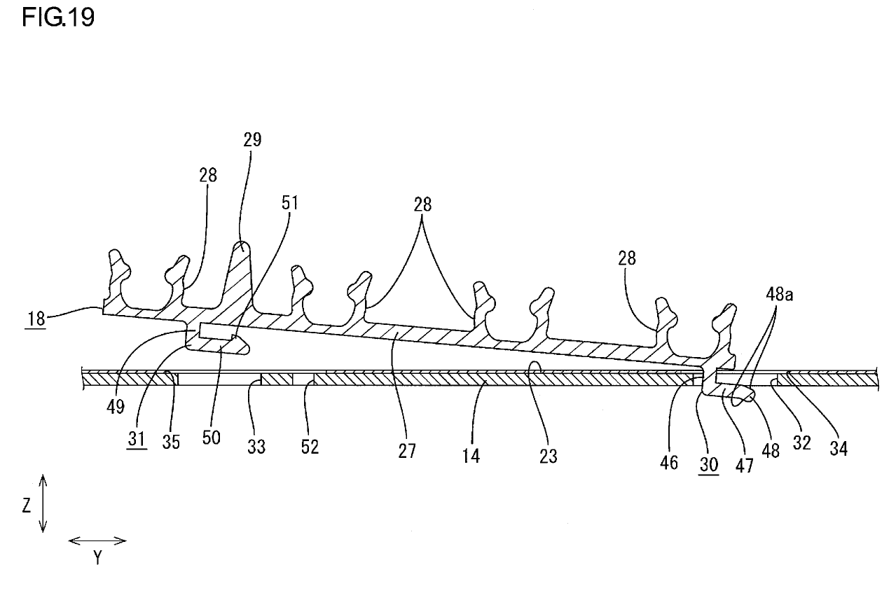

The first mounting portion 30 protrudes laterally from the edge portion of the main body 27, and thus when the lamp clip 18 is mounted to the chassis 14, the protruding tip portion of the first mounting portion 30 can be previously inserted into the first mounting hole 32 and the operation can be performed. In the mounting operation, as shown in FIG. 19, the body 27 is sloped so that the edge portion provided with the first mounting portion 30 is lowered. At this time, the support pin 29 gripped by the operator is provided eccentrically toward the edge portion on the side opposite the first mounting portion 30 previously inserted of the main body 27, thereby further improving workability in mounting the main body 27 to the chassis 14 while tilting the main body 27.

As shown in FIG. 5, the second mounting portion 31 has a substantially L shape on the front view like the first mounting portion 30, and includes a base portion 49 protruding from the back side surface of the main body 27 toward the back side (side of the chassis 14 along the Z-axis direction), and a piece 50 substantially squarely bent from the tip of the base portion 49 and protruding (extending) along the length direction of the main body 27. The base portion 49 is located in a substantially intermediate position between the lamp gripping portion 28 located at the edge portion on the side of the support pin 29 in the length direction of the main body 27 and the support pin 29. Specifically, the second mounting portion 31 is placed on the side opposite the first mounting portion 30 via the support pin 29 in the length direction of the main body 27. The base portion 49 is connected to the wide portion 27a of the main body 27 like the base portion 46 of the first mounting portion 30. A protruding size of the base portion 49 is substantially the same as that of the base portion 46 of the first mounting portion 30. The base portion 49 is provided in a substantially middle position in the width direction of the main body 27, that is, the same position as the base portion 46 of the first mounting portion 30.

The piece 50 is cantilevered to extend from the base portion 49 toward the support pin 29, and has a length such that a tip portion thereof is placed on the substantially directly back side of the support pin 29. The piece 50 is formed to be substantially parallel to the main body 27 over the entire length, and a locking protrusion 51 is provided on a surface of a protruding tip portion of the piece 50 opposing the main body 27. The locking protrusion 51 protrudes from the piece 50 so as to be close to the main body 27, and a tapered surface 51a is formed on a surface opposing the main body 27. The tapered surface 51a is formed continuously to the tip of the piece 50, and thus the piece 50 is tapered. A surface of the locking protrusion 51 opposing the base portion 49 is a vertical surface substantially in parallel with an outer surface of the base portion 49, and substantially straight along the direction (Z-axis direction) perpendicular to the sliding direction (Y-axis direction) of the lamp clip 18 with respect to the chassis 14, and this surface is a locking surface 51b to the chassis 14. The piece 50 has a rectangular shape as viewed from the back side, and a size (width) along the X-axis direction is set to be smaller than a size (length) along the Y-axis direction (sliding direction). The piece 50 has a length larger than that of the piece 47 or the first mounting hole 32 in the first mounting portion 30. The base portion 49 and the piece 50 have substantially the same width, which is set to be smaller than the width of the main body 27.

As shown in FIG. 11, the second mounting hole 33 and the second insertion hole 35 through which the second mounting portion 31 having the above-described configuration can be inserted are formed through the chassis 14 and the reflective sheet 23 in the thickness direction. Further, the locking hole 52 in which the locking protrusion 51 can be locked is formed through the chassis 14 in the thickness direction. The second mounting hole 33 formed in the chassis 14 has a rectangular shape on the plan view, and has a width and a length (size in a direction perpendicular to the Z-axis direction (inserting direction of the second mounting portion 31 into the second mounting hole 33)) set to be substantially the same as or slightly larger than the second mounting portion 31. The second mounting hole 33 has a length set to be larger than that of the first mounting hole 32 or the first mounting portion 30. The locking hole 52 is formed in a position between the first mounting hole 32 and the second mounting hole 33 and adjacent to the second mounting hole 33 with a predetermined space in the length direction. The locking hole 52 has a rectangular shape on the plan view, and has a width and a length set to be substantially the same as or slightly larger than those of the locking protrusion 51 of the second mounting portion 31. Meanwhile, the second insertion hole 35 formed in the reflective sheet 23 has a rectangular shape on the plan view, and has a width and a length set to be much larger than the sum of the widths and lengths of the second mounting hole 33 and the locking hole 52 so that the second insertion hole 35 can collectively surround the second mounting hole 33 and locking hole 52. A difference in size between the second mounting hole 33 and the locking hole 52 and the second insertion hole 35 is set to be the same as or larger than an assumed maximum value of a displacement amount that may occur between the reflective sheet 23 and the chassis 14 when the reflective sheet 23 is assembled to the chassis 14. Thus, the second mounting hole 33 and the locking hole 52 are reliably placed inside the second insertion hole 35 to avoid the reflective sheet 23 from covering the second mounting hole 33 or the locking hole 52. Conversely, the rims of the second mounting hole 33 and the locking hole 52 in the chassis 14 are not covered by the reflective sheet 23, and directly face the back surface of the main body 27 without via the reflective sheet 23.

As shown in FIG. 20, the second mounting portion 31 is inserted into the second insertion hole 35 and the second mounting hole 33 and protruded on the back side of the chassis 14, and the main body 27 is slid in a protruding direction (to the right in FIG. 20 along the Y-axis direction) of the piece 50. Then, as shown in FIG. 12, the piece 50 is placed on the back side of the front portion in the sliding direction (mounting direction) of the rim of the second mounting hole 33, and the locking protrusion 51 at the tip portion enters the locking hole 52 and is locked to the hole edge. Thus, the chassis 14 is held between the connecting portion of the main body 27 to the support pin 29 and the piece 50 of the second mounting portion 31, and the locking surface 51b of the locking protrusion 51 is locked to the hole edge of the locking hole 52 to control movement to the back side in the mounting direction (removing direction). A held portion of the chassis 14 held between the main body 27 and the second mounting portion 31 is a portion between the second mounting hole 33 and the locking hole 52. The second insertion hole 35 has a width smaller than the width of the main body 27, and also a distance from a lateral end surface on the side of the support pin 29 in the rear end position in the sliding direction of the main body 27 to the base portion 49 is larger than a sliding amount in mounting. Thus, in the mounting state, the second mounting hole 33 and the second insertion hole 35 are covered (blocked) by the main body 27 to restrict the holes 33 and 35 from being exposed to the outside of the main body 27.

The lamp clip 18 has the above-described design in which the mounting direction to the chassis 14 is specified so that the support pin 29 eccentrically placed is directed toward the reference line L1 (eccentric toward the reference line L1). Thus, the lamp clip 18 has a control structure for controlling mounting in a direction opposite the specified mounting direction. The control structure will be described below in detail.

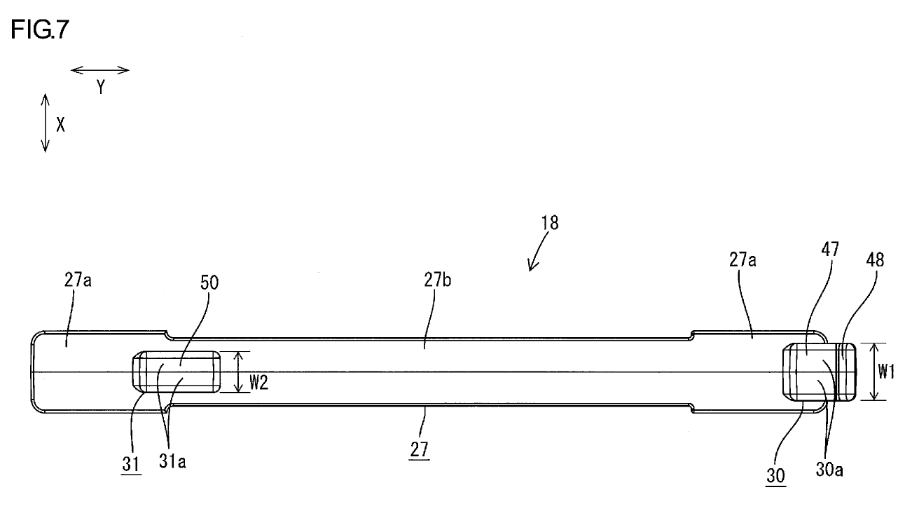

As shown in FIG. 7, the first mounting portion 30 and the second mounting portion 31 have different widths W1 and W2 (sizes in parallel with and perpendicular to the sliding direction), and correspondingly thereto, as shown in FIG. 11, the first mounting hole 32 and the second mounting hole 33 in the chassis 14 have different widths W3 and W4 (sizes in parallel with and perpendicular to the sliding direction). Specifically, the width W1 of the first mounting portion 30 is larger than the width W2 of the second mounting portion 31, and correspondingly thereto, the width W3 of the first mounting hole 32 is larger than the width W4 of the second mounting hole 33. The width W1 of the first mounting portion 30 is larger than the width W4 of the second mounting hole 33, and the width W3 of the first mounting hole 32 is larger than the width W2 of the second mounting portion 31. The widths of the first insertion hole 34 and the second insertion hole 35 in the reflective sheet 23 have the same relationship as the first mounting hole 32 and the second mounting hole 33 in the chassis 14.

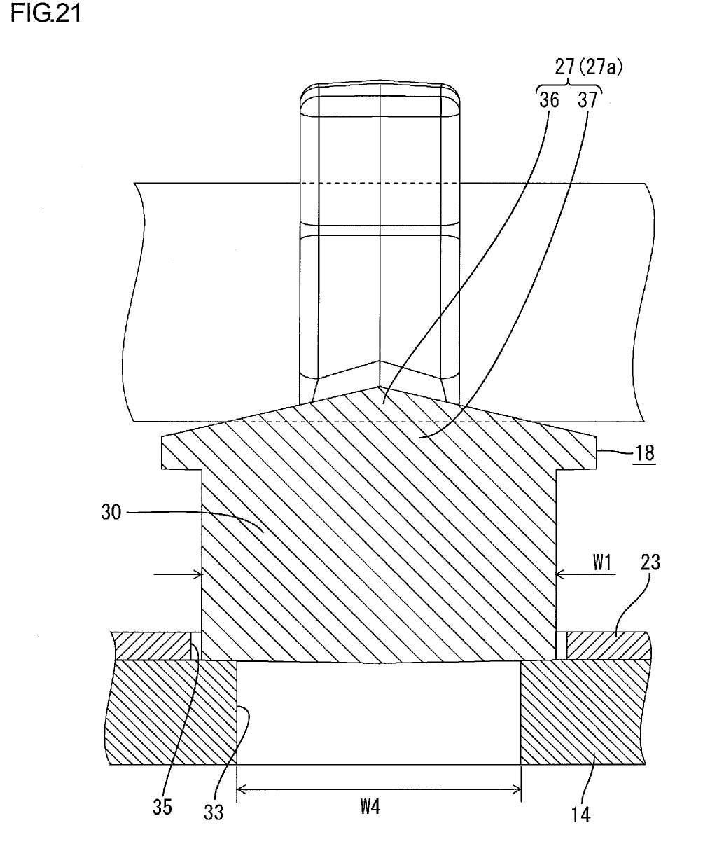

Thus, in the case where the lamp clip 18 is mounted to the chassis 14 in the mounting direction opposite the normal direction, the first mounting portion 30 is about to enter the second mounting hole 33 and the second mounting portion 31 is about to enter the first mounting hole 32 with the mounting portions 30 and 31 being in misalignment with the originally corresponding mounting holes 32 and 33. However, as shown in FIG. 21, the width W1 of the first mounting portion 30 is larger than the width W4 of the second mounting hole 33, and thus the edge portion in the width direction of the first mounting portion 30 interferes with the edge portion in the width direction in the rim of the second mounting hole 33 to control the mounting operation with the main body 27 being raised from the chassis 14. Therefore, the lamp clip 18 is less likely to be mounted in the wrong mounting direction. It can be said that the edge portion in the width direction of the rim of the second mounting hole 33 functions as a mounting control portion that controls mounting of the lamp clip 18.

This embodiment has the above-described structure, and an operation thereof will be described next. The liquid crystal panel 11 and the backlight unit 12 are separately produced and assembled to each other using the bezel 13 or the like to produce the liquid crystal display device 10 shown in FIGS. 3 and 4. Then, an assembling operation of the backlight unit 12, particularly, the mounting operation of the lamp clip 18 will be described in detail.

When the reflective sheet 23 is provided on the inside of the chassis 14, as shown in FIG. 10, the corresponding mounting holes 32 and 33 and the locking hole 52 are aligned to face the insertion holes 34 and 35, and then each lamp clip 18 is mounted to the chassis 14. The mounting direction of the lamp clip 18 to the chassis 14 is different depending on which of the regions A1 and A2 of the chassis 14 the lamp clip 18 is mounted to. Specifically, the mounting directions of the lamp clip 18 are set in opposite directions in the first region A1 and the second region A2 at the reference line L1 on the chassis 14 as a border, a first mounting direction (mounting direction with the support pin 29 being eccentric downward in FIG. 9) is set in the first region A1, and a second mounting direction opposite the first mounting direction (mounting direction with the support pin 29 being eccentric upward in FIG. 9) is set in the second region A2. Thus, in mounting the lamp clip 18, the mounting direction corresponding to the mounting position to the chassis 14 needs to be selected.

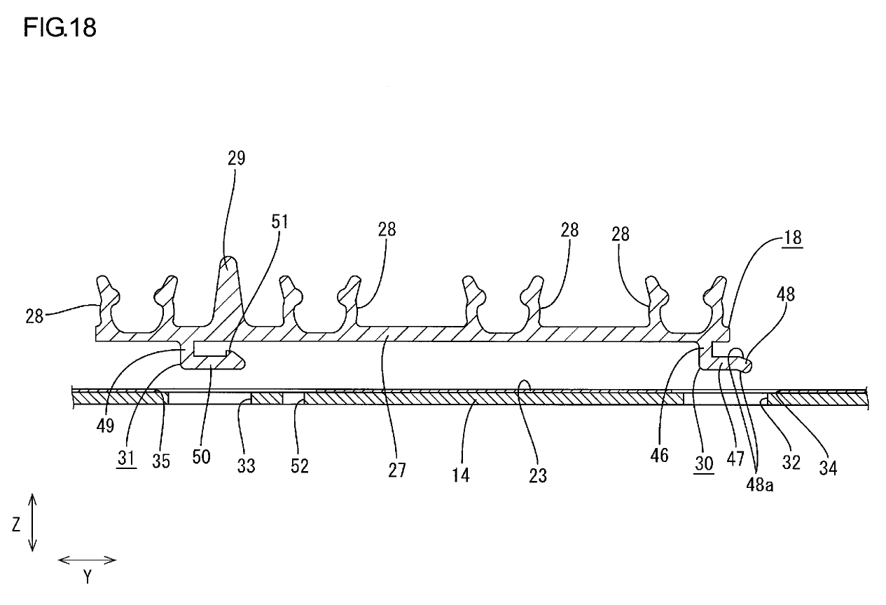

The case where the lamp clip 18 is mounted in the normal mounting direction will be described. When the support pin 29 eccentrically placed on the main body 27 is gripped, the lamp clip 18 is moved from the state shown in FIG. 18 in the Z-axis direction so as to be close to the chassis 14, the main body 27 is positioned so that the edge portion on the side opposite the support pin 29 is lowered, and the first mounting portion 30 protruding from the edge portion forward in the mounting direction is previously inserted into the first insertion hole 34 and the first mounting hole 32. At this time, as shown in FIG. 19, the guide surface 48a of the guide portion 48 formed at the front edge portion of the first mounting portion 30 is brought into slide contact with the hole edge part of the first mounting hole 32 to achieve smooth insertion. Then, the main body 27 is displaced to be parallel to the bottom plates of the chassis 14 and the reflective sheet 23, and the second mounting portion 31 is inserted into the second insertion hole 35 and the second mounting hole 33. If the piece 47 of the first mounting portion 30 protrudes on the back side of the chassis 14, the main body 27 may be slightly slid in the extending direction of the pieces 47 and 50 before the second mounting portion 31 is inserted.

As shown in FIG. 20, when the main body 27 is slid in the extending direction of the pieces 47 and 50 (to the right in FIG. 20 along the Y-axis direction) from the state where the pieces 47 and 50 of the first mounting portion 30 and the second mounting portion 31 protrude on the back side of the chassis 14, the pieces 47 and 50 oppose the back surface of the chassis 14, and abut or are brought close to the front portion in the mounting direction of the hole edge parts of the mounting holes 32 and 33. In this process, the locking protrusion 51 of the second mounting portion 31 rides up onto the back surface of the chassis 14, and the piece 50 is once elastically deformed. When the lamp clip 18 is slid a predetermined distance, as shown in FIG. 12, the locking protrusion 51 enters the locking hole 52 and the piece 50 elastically returns, and the locking surface 51b of the locking protrusion 51 is locked to the inner peripheral surface of the locking hole 52. Therefore, the lamp clip 18 is less likely to be accidentally moved in the direction opposite the mounting direction (removing direction, to the left in FIG. 12). At this time, the piece 50 returns and abuts against the back surface of the chassis 14 and produces sound, and thus the operator can obtain strong click feeling, and can reliably slide the lamp clip 18 to the normal mounting position (retaining position).

In this state, the reflective sheet 23 and the chassis 14 are held between the pieces 47 and 50 of the mounting portions 30 and 31 and the main body 27, and thus the lamp clip 18 is held in the mounting state to the chassis 14. In this state, even if vibration or the like is applied and a force to displace the lamp clip 18 along the Z-axis direction to the front side is applied, the pieces 47 and 50 of the mounting portions 30 and 31 engage the back surface of the chassis 14 to control the displacement of the lamp clip 18 in the Z-axis direction. The pair of mounting portions 30 and 31 are inserted into the mounting holes 32 and 33 to restrict rotation of the lamp clip 18.

Meanwhile, a case where the lamp clip 18 is mounted in the direction opposite the normal mounting direction (a mounting state different from a normal state) will be described. Even if a user mistakenly tries to mount the lamp clip 18 in the wrong mounting direction, the mounting portions 30 and 31 having the different widths W1 and W2 are in misalignment with the corresponding mounting holes 32 and 33. Thus, as shown in FIG. 21, the edge portion in the width direction of the first mounting portion 30 having the comparatively (relatively) large width W1 (relatively larger first mounting portion 30) reliably interferes with the edge portion in the width direction of the rim of the second mounting hole 33 having the comparatively (relatively) small width W4 (relatively smaller second mounting hole 33). Further, the second mounting portion 31 and the second mounting hole 33 have the lengths longer than the lengths of the first mounting portion 30 and the first mounting hole 32, and thus the edge portion in the length direction of the second mounting portion 31 interferes with the edge portion in the length direction of the rim of the first mounting hole 32. Thus, the first mounting portion 30 cannot be inserted into the second mounting hole 33, and the main body 27 is raised from the chassis 14 and the reflective sheet 23. Thus, the operator can reliably find the wrong mounting direction.

When the lamp clip 18 is mounted in the mounting direction opposite the normal direction, and the lamp clip 18 is displaced from a position to which the lamp clip 18 is to be mounted in the chassis 14 in the length direction of the main body 27 (in the short side direction of the chassis 14), the first mounting portion 30 may enter the first mounting hole 32 or the second mounting portion 31 may enter the second mounting hole 33. However, in that case, the other mounting portion different from one mounting portion that may enter the hole is in misalignment with the corresponding mounting hole, and the other mounting portion is placed on the reflective sheet 23 and the main body 27 is raised, and thus the operator can find the wrong mounting direction. In other words, the mounting holes 32 and 33 arranged in the short side direction of the chassis 14 are placed in misalignment with the mounting portions 30 and 31 of the lamp clip 18 when the lamp clips 18 to be mounted to positions adjacent to each other in the short side direction are mounted in the mounting direction opposite the normal direction, and the lamp clip 18 is displaced from the position to which the lamp clip 18 is to be mounted in the length direction of the main body 27.

As described above, mounting of each lamp clip 18 is controlled if the mounting direction (mounting position, mounting state) does not correspond to the region A1 or A2 of the chassis 14. Thus, with all the lamp clips 18 being mounted to the chassis 14, as shown in FIG. 9, the support pins 29 of the lamp clips 18 are reliably aligned eccentrically toward the reference line L1. Thus, when the diffuser plate 15a is mounted later, the screen middle side of the diffuser plate 15a can be satisfactorily supported by the support pins 29 to restrict the diffuser plate 15a from being bent or warped toward the cold cathode tube 17 when thermal expansion or thermal contraction occurs. In particular, in this embodiment, the liquid crystal panel 11 is directly received by the diffuser plate 15a and the optical sheet 15b to reduce a thickness of the liquid crystal display device 10, and thus a slight distance or little distance is ensured between the liquid crystal panel 11 and the diffuser plate 15a and the optical sheet 15b. In such a case, outer rims of the diffuser plate 15a and the optical sheet 15b tend to be easily held and constrained between the holder 20 and the liquid crystal panel 11. This easily causes thermal expansion and contraction eccentrically (concentrically) on the screen middle side, but the support pins 29 are collectively provided on the screen middle side as described above to satisfactorily control warpage or bending of the diffuser plate 15a, which is extremely suitable for reducing the thickness of the liquid crystal display device 10. Conversely, if mounting in the mounting direction opposite the normal direction is allowed, the support pins 29 are eccentrically provided on the side away from the reference line L1, which may reduce a supporting function of the diffuser plate 15a, but such a situation can be reliably avoided.

After the lamp clip 18 is mounted as described above, each cold cathode tube 17 is mounted to each lamp gripping portion 28, and then the holder 20 is mounted. Then, the diffuser plate 15a and the optical sheet 15b are stacked, and the liquid crystal panel 11 is further placed from the front side, and the bezel 13 is assembled, and thus the liquid crystal display device 10 is assembled.

Next, an operation when each cold cathode tube 17 in the backlight unit 12 is lit will be described. As shown in FIG. 12, a linear light emitted from each cold cathode tube 17 is applied directly to the diffuser plate 15a or reflected by the reflective sheet 23 or the lamp clip 18 and then applied to the diffuser plate 15a, converted into a planar light in the process of passing through the diffuser plate 15a and the optical sheet 15b, and then applied to the liquid crystal panel 11. Next, a relationship between the light emitted from the cold cathode tube 17 and the lamp clip 18 will be described in detail.

The cold cathode tube 17 is gripped by the lamp gripping portion 28, and supported at the three points by the first support point S1 located directly below the center C of the cold cathode tube 17 and the second support point S2 and the third support point S3 on the holding protrusions 41 on the bottom surface of the lamp gripping portion 28. Between the support points S1 to S3, a circumferential gap is ensured between the outer peripheral surface of the cold cathode tube 17 and the inner peripheral surface of the arm portion 39. Thus, with decreasing thickness of the backlight unit 12, the cold cathode tube 17 is held in a position lower than the vertex P1 of the main body 27, and even if a slight distance is ensured between the cold cathode tube 17 and the reflective sheet 23, the light emitted from the cold cathode tube 17 can be efficiently emitted to the outside of the lamp gripping portion 28 through the gap.

In the bottom surface between the arm portions 39 in the inner peripheral surface of the lamp gripping portion 28, as shown in FIG. 15, the pair of sloped surfaces 44 are formed having the highest middle position (vertex P2) in the length direction (X-axis direction) of the cold cathode tube 17 and the lowest opposite end positions, and a gap between the sloped surface 44 and the cold cathode tube 17 extends from the middle position toward the opposite end positions, that is, has a skirt shape. Thus, the light emitted form the cold cathode tube 17 toward the bottom surface (side of the chassis 14, directly below, directly back) of the lamp gripping portion 28 passes through the gap extending outward of the lamp gripping portion 28 in the length direction of the cold cathode tube 17 and is efficiently emitted to the outside of the lamp gripping portion 28. At this time, the light emitted from the cold cathode tube 17 toward the bottom surface of the lamp gripping portion 28 passes through the gap and is incident on the sloped surface 44, and is thus angled to be reflected outward of the lamp gripping portion 28 in the length direction of the cold cathode tube 17, and thus few light is returned into the cold cathode tube 17 to further improve light taking efficiency.

The bottom portion 43 of the lamp gripping portion 28 has a symmetrical shape, and the sloped surfaces 44 have the same slope angle, and thus the light can be emitted from the vertex P2 of the sloped surfaces 44 substantially uniformly to the left and right in FIG. 15 between the cold cathode tube 17 and the bottom portion 43, and is further effective for reducing luminance unevenness. Further, the raised portion 37 on the bottom portion 43 of the lamp gripping portion 28 has a triangular sectional shape, and thus the sloped surface 44 formed over the entire surface of the raised portion 37 of the bottom portion 43 can reflect the light toward the diffuser plate 15a, and the slope angle of the sloped surface 44 can be more gentle than a case where the raised portion 37 has a trapezoidal sectional shape or the like, which is further suitable for providing uniform light reflection efficiency.

Further, the extended sloped surface 45 having the same slope as the sloped surface 44 is formed over the entire inner peripheral surfaces of the arm portion 39, the holding protrusion 41, and the guide portion 42 besides the bottom surface of the lamp gripping portion 28, and thus a gap progressively extending from the middle position toward the opposite end positions in the length direction of the cold cathode tube 17 is formed between the extended sloped surface 45 and the cold cathode tube 17. Thus, the light emitted from the cold cathode tube 17 toward the bottom surface and also lights emitted to both the lateral sides or the front side can be efficiently emitted through the gap between the cold cathode tube 17 and the extended sloped surface 45 to the outside of the lamp gripping portion 28, and the light having passed through the gap is incident on the extended sloped surface 45 and angled to be reflected outward of the lamp gripping portion 28 in the length direction of the cold cathode tube 17, thereby further improving light taking efficiency.

Further, as shown in FIG. 16, the holding protrusions 41 of the lamp gripping portion 28 that covers the cold cathode tube 17 from the front side (light output side) are tapered toward the inner ends, and thus a covering area of the cold cathode tube 17 by the holding protrusion 41 as viewed from the front side is smaller than a case where the holding protrusion 41 has a fixed width. This can increase an effective light emitting area of the cold cathode tube 17 and ensure a sufficient amount of light provided by the cold cathode tube 17. Therefore, the holding protrusion 41 that covers the cold cathode tube 17 from the front side is less likely to be recognized as a dark portion. The holding protrusion 41 (lamp gripping portion 28) has a symmetrical shape, and the tapered surfaces 41a have the same slope angle, which is further effective for reducing luminance unevenness. Further, as shown in FIG. 17, the extended tapered surface 39a is formed so that the holding protrusion 41 and also the arm portion 39 and the guide portion 42 are tapered over the entire lengths, and thus a covering area of the cold cathode tube 17 by the arm portion 39, the holding protrusion 41, and the guide portion 42 surrounding the outer peripheral surface of the cold cathode tube 17 is circumferentially minimized, which is further effective for increasing the amount of light.

In addition, between the lamp gripping portions 28 in the lamp clip 18 (between the cold cathode tubes 17), as shown in FIGS. 13 and 14, the raised portion 37 having the sloped surfaces 38 having downward slopes from the middle position to the opposite end positions in the width direction are formed in the main body 27, and thus the light emitted from the cold cathode tube 17 is incident on the sloped surfaces 38 and satisfactorily reflected toward the diffuser plate 15a. At this time, the light reflected by the sloped surface 38 is angled outward of the main body 27 in the length direction of the cold cathode tube 17, which is suitable for reducing luminance unevenness. Also, the opposite edge portions in the width direction along the length direction of the raised portion 37 are thinner over the entire region than the middle portion and there is little step from the base 36, and thus there is few shadow portions (opposite end surfaces in the width direction of the raised portion 37) in the raised portion 37, and the raised portion 37 is hardly visually identified as a shadow. Further, the raised portion 37 has a triangular sectional shape, and thus the sloped surfaces 38 formed over the entire surface of the raised portion 37 can reflect the light toward the diffuser plate 15a. Also, the slope angle of the sloped surface 38 can be more gentle than a case where the raised portion 37 has a trapezoidal sectional shape or the like, which is further suitable for providing uniform light reflection efficiency. The thickness T1 at the vertex P1 that is the top of the raised portion 37 is larger than the thickness T2 of the base 38, and thus a large amount of light is reflected by the raised portion 37. Therefore, the base 38 is less likely to be recognized as a dark portion. This can provide uniform light reflection efficiency of the surface of the main body 27 as much as possible. Therefore, a dark portion is less likely to be present in the main body 27 as much as possible.

Further, the base 36 having a predetermined thickness is formed on the back side of the raised portion 37, and thus even if the light is incident on the thin opposite edge portions in the width direction in the raised portion 37, the light is restricted from passing through the main body 27. On the back side of portions in the main body 27 corresponding to the insertion holes 34 and 35 in the reflective sheet 23, as shown in FIG. 13, the chassis 14 is directly placed without via the reflective sheet 23 because the insertion holes 34 and 35 in the reflective sheet 23 are slightly larger than the mounting holes 32 and 33 in the chassis 14. Thus, if the light can pass through the main body 27, the chassis 14 having lower light reflectivity than the reflective sheet 23 may be visually identified as a dark portion. However, as described above, the base 36 having the sufficient thickness is formed on the back side of the thin portion of the raised portion 37, and block the mounting holes 32 and 33 and the insertion holes 34 and 35, thereby avoiding the light from passing through the main body 27 and shadows of areas inside the insertion holes 34 and 35 in the chassis 14 are less likely to be recognized from the front side.

As described above, according to this embodiment, taking efficiency of the light emitted from the cold cathode tube 17 is extremely improved, and parts of the lamp clip 18 and the chassis 14 are less likely to be recognized as a dark portion. Thus, when a distance between the liquid crystal panel 11 and the diffuser plate 15a and the optical sheet 15b, a distance between the diffuser plate 15a and the cold cathode tube 17 and the lamp clip 18, and a distance between the cold cathode tube 17 and the reflective sheet 23 are reduced with decreasing thickness of the backlight unit 12, luminance unevenness is less likely to occur, and thus even an ultrathin liquid crystal display device 10 can provide satisfactory display performance.

A diameter of the cold cathode tube 17 used in this embodiment is 4.0 mm, a distance between the cold cathode tube 17 and the reflective sheet 23 is 0.8 mm, a distance between the adjacent cold cathode tubes 17 is 16.4 mm, and a distance between the cold cathode tube 17 and the diffuser plate 15a is 2.7 mm. As such, the thicknesses of the components are reduced in the backlight unit 12, and the distance between the cold cathode tube 17 and the diffuser plate 15a and the distance between the cold cathode tube 17 and the reflective sheet 23 are particularly reduced. By the reduction in thickness of the backlight unit 12, the thickness of the liquid crystal display device 10 (that is, the thickness from the surface of the liquid crystal panel 11 to the back surface of the backlight unit 12) is 16 mm, and the thickness of the television receiver apparatus TV (that is, the thickness from the surface of the front side cabinet Ca to the back surface of the back side cabinet Cb) is 34 mm, and a thin television receiver apparatus is achieved.

### Second Embodiment

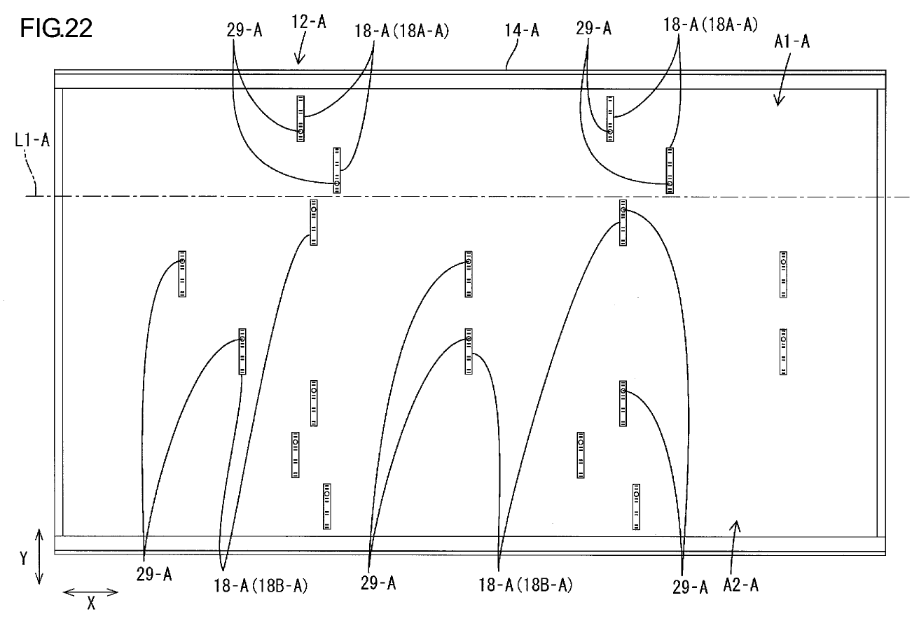

A second embodiment of the present invention will be described with reference to FIG. 22. In the second embodiment, a position of a reference line L1-A set in a chassis 14-A is changed. In the second embodiment, the same components as in the first embodiment are denoted by the same reference numerals with a suffix -A added to the ends, and overlapping descriptions on structures, operations, and advantages will be omitted.

As described in the first embodiment, a diffuser plate (not shown) integrated into a backlight unit 12-A may be thermally expanded or contracted, and which portion in a plane thereof is easily expanded or contracted tends to depend on thermal distribution when the backlight unit 12-A is lit or extinguished. With uniform thermal distribution, the diffuser plate is easily expanded or contracted on a screen middle side, but with uneven thermal distribution, a portion that is easily expanded or contracted in the diffuser plate may be shifted from the screen middle. Thus, thermal distribution of the backlight unit 12-A is analyzed to identify the portion that is easily expanded or contracted in the diffuser plate, and according thereto, the position of the reference line L1-A as a reference for eccentrically placing a support pin 29-A on each lamp clip 18-A can be set.

Specifically, as shown in FIG. 22, when the diffuser plate is easily expanded or contracted in an upper position in the drawing than a middle position in a short side direction of the chassis 14-A, the reference line L1-A is shifted upward in the drawing from the middle position in the short side direction. It is sufficient that in the chassis 14-A, an upper side in FIG. 22 of the reference line L1-A eccentrically placed is referred to as a first region A1-A where a first lamp clip group 18A-A is provided, and a lower side in the drawing is referred to as a second region A2-A where a second lamp clip group 18B-A is provided. Thus, each support pin 29-A is placed closer to the portion that is easily expanded or contracted in the diffuser plate, thereby reliably reducing bending or warpage of the diffuser plate. At this time, the number of lamp clips 18-A may be different between the first lamp clip group 18A-A and the second lamp clip group 18B-A. As described above, a supporting state for the diffuser plate can be optimized correspondingly to design of the backlight unit 12-A.

In the backlight unit 12-A, convection that is rising of heated air may occur with lighting, and in that case, an upper portion of the backlight unit 12-A in a vertical direction in using a liquid crystal display device tends to be higher in temperature than a lower portion. The diffuser plate tends to be more significantly expanded or contracted in a high temperature region, and thus in such a case, the reference line L1-A is effectively shifted vertically upward in using the liquid crystal display device.

### Third Embodiment

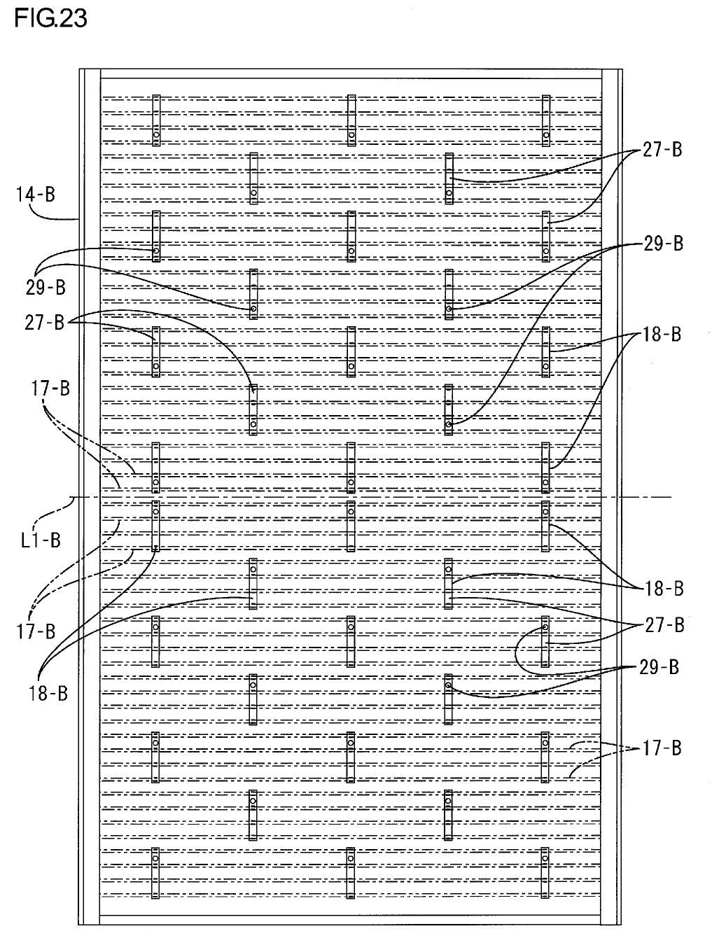

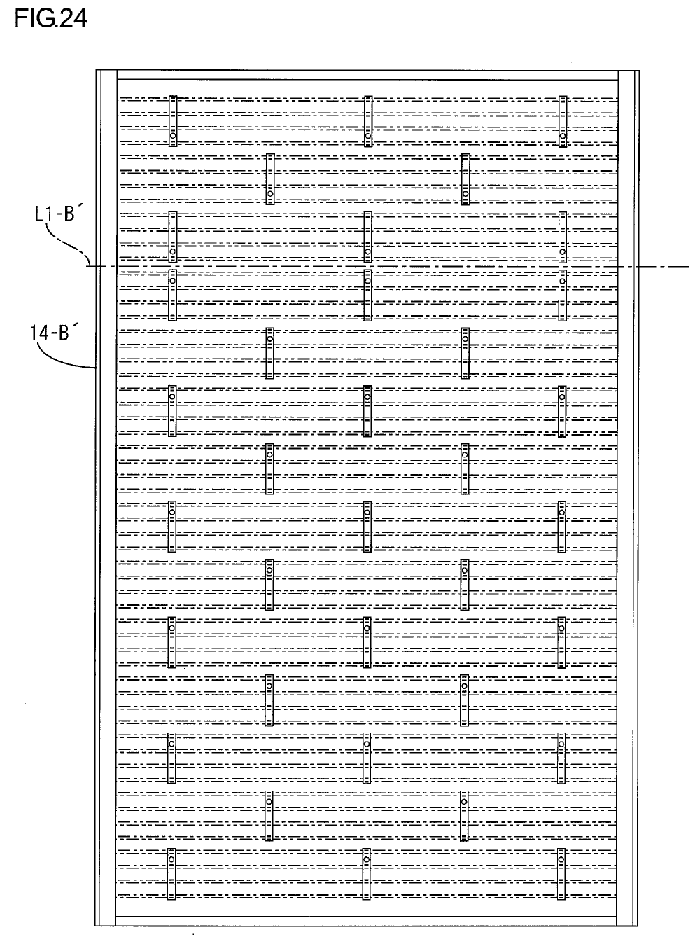

A third embodiment of the present invention will be described with reference to FIG. 23 or 24. In the third embodiment, positions of a cold cathode tube 17-B or the like and a reference line L-B in a chassis 14-B are changed. In the third embodiment, the same components as in the first embodiment are denoted by the same reference numerals with a suffix -B added to the ends, and overlapping descriptions on structures, operations, and advantages will be omitted.

As shown in FIG. 23, the cold cathode tube 17-B is mounted to the chassis 14-B with a length direction matching a short side direction of the chassis 14-B (diffuser plate), and a plurality of cold cathode tubes 17-B are arranged in parallel. A lamp clip 18-B for holding each cold cathode tube 17-B is mounted to the chassis 14-B with a length direction of a main body 27-B matching a long side direction of the chassis 14-B (diffuser plate). The reference line L1-B as a reference of a mounting direction of each lamp clip 18-B on which a support pin 29-B is eccentrically placed is set to cross along the short side direction through a middle position in the long side direction of the chassis 14-B (diffuser plate). Thus, also for a liquid crystal display device used with the long side direction of the chassis 14-B matching a vertical direction of the liquid crystal display device, bending or warpage of the diffuser plate can be satisfactorily controlled.

As shown in FIG. 24, a position of a reference line L1-B′ may be, of course, shifted from a middle position in a long side direction of a chassis 14-B′ by applying a design idea described in the second embodiment.

### Fourth Embodiment

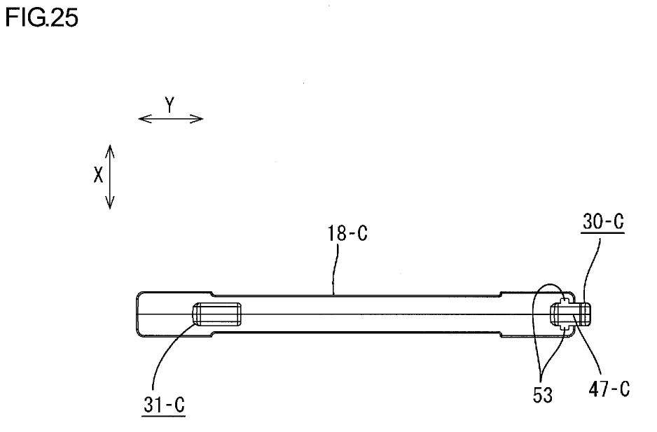

A fourth embodiment of the present invention will be described with reference to FIGS. 25 to 28. In the fourth embodiment, a structure for controlling mounting of a lamp clip 18-C in a wrong direction is changed. In the fourth embodiment, the same components as in the first embodiment are denoted by the same reference numerals with a suffix -C added to the ends, and overlapping descriptions on structures, operations, and advantages will be omitted.

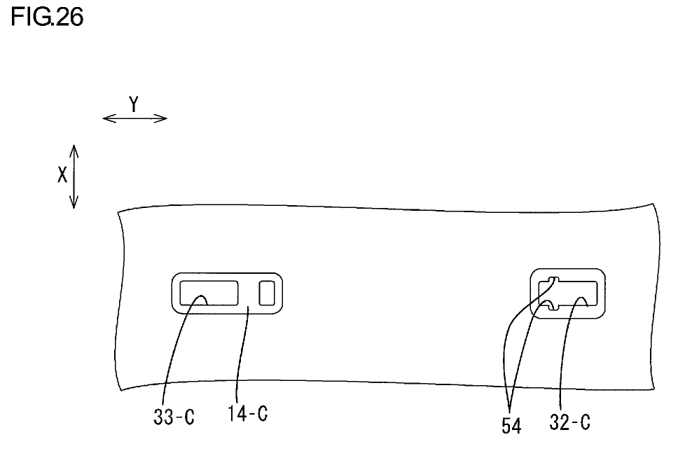

A first mounting portion 30-C and a second mounting portion 31-C in the lamp clip 18-C have substantially the same width as shown in FIG. 25. From opposite side surfaces of a piece 47-C of the first mounting portion 30-C, a pair of control portions 53 are formed to laterally protrude. Thus, the first mounting portion 30-C is formed so that portions corresponding to the control portions 53 are partially wide. Meanwhile, a first mounting hole 32-C and a second mounting hole 33-C in a chassis 14-C have the same width matching the mounting portions 30-C and 31-C as shown in FIG. 26, but the first mounting hole 32-C is formed with notches 54 corresponding to the control portions 53 and formed to be partially wide.

Thus, when the lamp clip 18-C is to be mounted in a mounting direction different from a normal direction, the control portions 53 of the first mounting portion 30-C interfere with a rim of the second mounting hole 33-C. This can reliably control mounting of the lamp clip 18-C in a wrong direction.

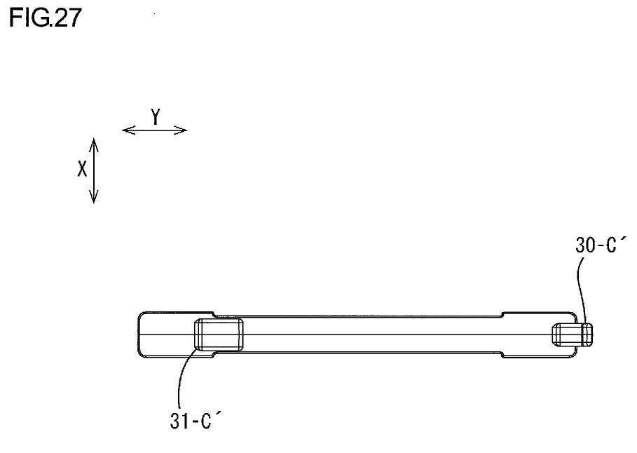

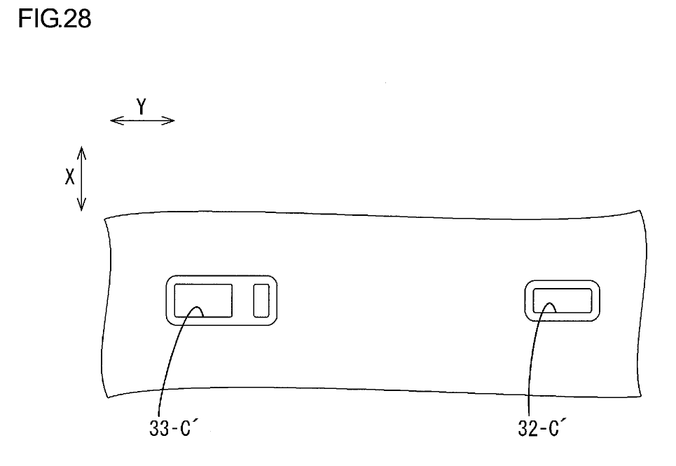

As a variation aspect of a structure for controlling mounting of the lamp clip 18-C in a wrong direction, for example, as shown in FIGS. 27 and 28, a second mounting portion 31-C′ and a second mounting hole 33-C′ may have larger widths than a first mounting portion 30-C′ and a first mounting hole 32-C′.

### Fifth Embodiment

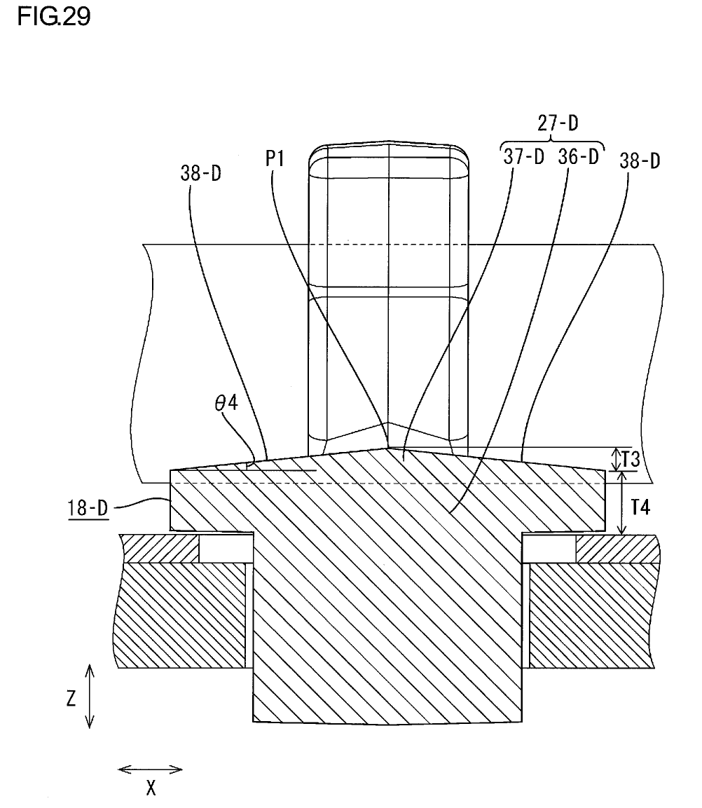

A fifth embodiment of the present invention will be described with reference to FIG. 29. In the fifth embodiment, a sectional shape of a main body 27-D is changed. In the fifth embodiment, the same components as in the first embodiment are denoted by the same reference numerals with a suffix -D added to the ends, and overlapping descriptions on structures, operations, and advantages will be omitted.

A main body 27-D includes, as shown in FIG. 29, a base 36-D having a block-shaped sectional shape, and a raised portion 37-D having a triangular sectional shape placed on the base 36-D, and a thickness T3 at a vertex P1 of the raised portion 37-D is set to be smaller than a thickness T4 of the base 36-D. The sum of the thickness T3 of the raised portion 37-D and the thickness T4 of the base 36-D (thickness of the main body 27-D) is set to be the same as the sum of the thickness T1 of the raised portion 37 and the thickness T2 of the base 36 in the first embodiment (see FIG. 13). Thus, a slope angle θ4 of each sloped surface 38-D of the raised portion 37-D is smaller than the slope angles θ1 and θ2 of the sloped surface 38 in the first embodiment. At this time, the slope angle θ4 of the sloped surface 38-D may be the same as the slope angle θ3 (see FIG. 15) of the sloped surface 44 of the bottom surface of the lamp gripping portion 28 in the first embodiment, which can provide more uniform reflection efficiency of the surface of the lamp clip 18-D.

### Sixth Embodiment

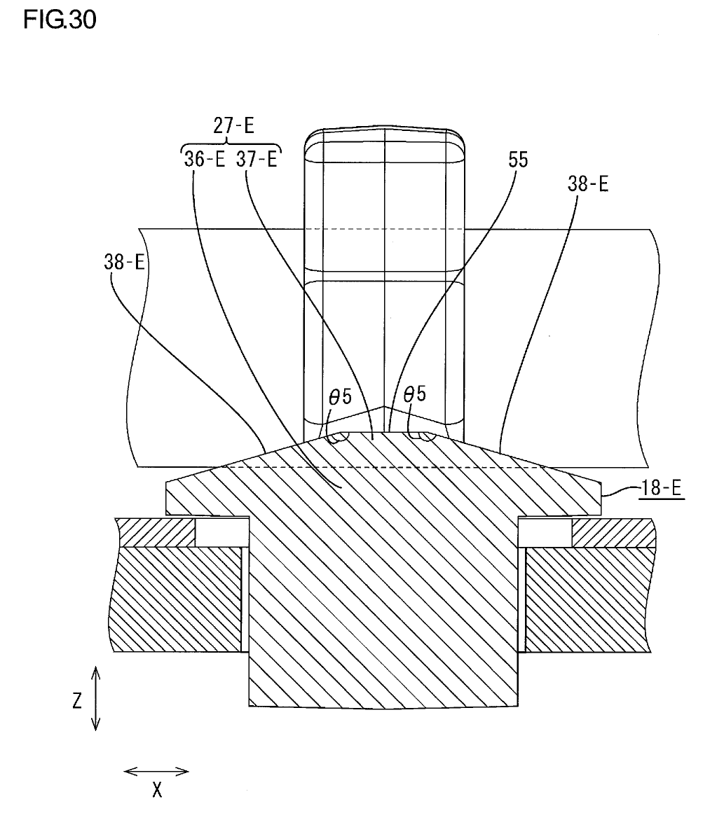

A sixth embodiment of the present invention will be described with reference to FIG. 30. In the sixth embodiment, a sectional shape of a main body 27-E is changed. In the sixth embodiment, the same components as in the first embodiment are denoted by the same reference numerals with a suffix -E added to the ends, and overlapping descriptions on structures, operations, and advantages will be omitted.

A raised portion 37-E that constitutes a main body 27-E has a substantially trapezoidal sectional shape as shown in FIG. 30. A pair of sloped surfaces 38-E are formed on opposite side surfaces in a width direction of the raised portion 37-E, and vertexes of the sloped surfaces 38-E are connected by a flat surface 55 parallel to an X-axis direction. In the raised portion 37-E, an angle θ5 formed by the flat surface 55 and each of the sloped surfaces 38-E is larger than the angle (see FIG. 13) formed by the sloped surfaces 38 of the raised portion 37 in the first embodiment. Thus, when the lamp clip 18-E is molded of resin, a molten resin material easily uniformly flows into a mold, thereby reducing poor molding.

### Seventh Embodiment

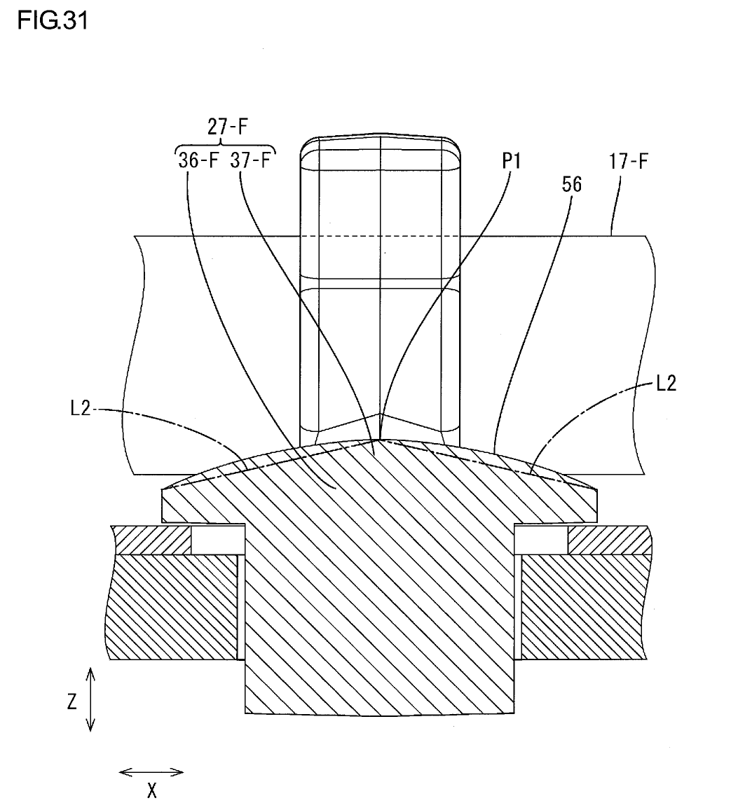

A seventh embodiment of the present invention will be described with reference to FIG. 31. In the seventh embodiment, a sectional shape of a main body 27-F is changed. In the seventh embodiment, the same components as in the first embodiment are denoted by the same reference numerals with a suffix -F added to the ends, and overlapping descriptions on structures, operations, and advantages will be omitted.

A raised portion 37-F that constitutes the main body 27-F has a substantially arcuate sectional shape as shown in FIG. 31. An arcuate curved surface 56 is formed over the entire circumferential surface of the raised portion 37-F. The curved surface 56 is expanded outward of an outside of a line L2 connecting opposite end positions (opposite edge portions in a length direction of a cold cathode tube 17-F) in a width direction of the raised portion 37-F and a vertex P1. When a light is reflected by the curved surface 56, the reflected light is appropriately scattered without traveling in a particular direction. This is suitable for providing uniform reflection efficiency. Also, higher strength can be obtained than a case where a raised portion is formed to be recessed inward of the line L2.

### Eighth Embodiment

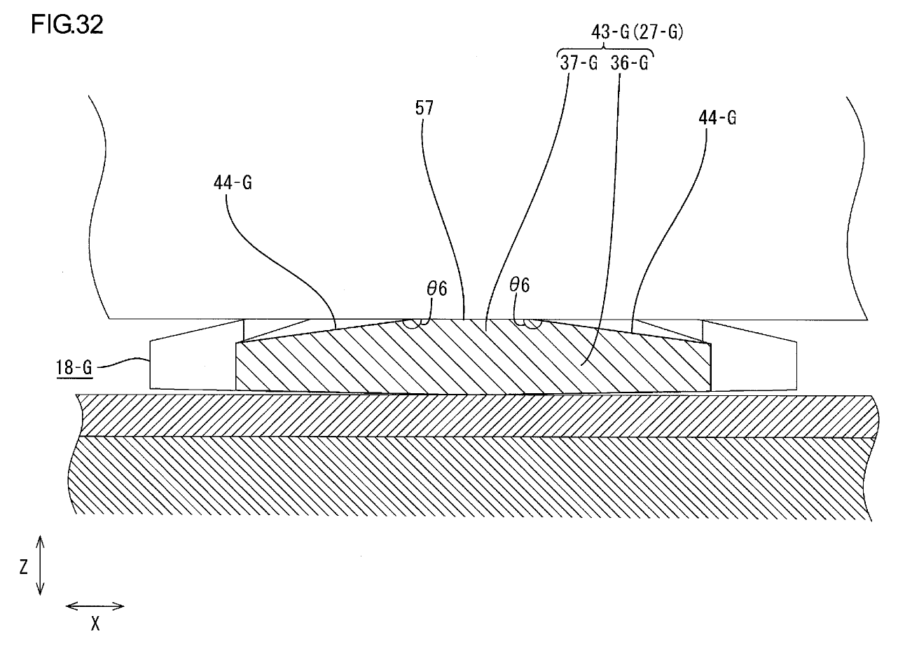

An eighth embodiment of the present invention will be described with reference to FIG. 32. In the eighth embodiment, a sectional shape of a bottom portion 43-G of a lamp gripping portion 28-G is changed. In the eighth embodiment, the same components as in the first embodiment are denoted by the same reference numerals with a suffix -G added to the ends, and overlapping descriptions on structures, operations, and advantages will be omitted.

A raised portion 37-G that constitutes the bottom portion 43-G of the lamp gripping portion 28-G has a substantially trapezoidal sectional shape as shown in FIG. 32. A pair of sloped surfaces 44-G is formed on opposite side surfaces of the raised portion 37-G of the bottom portion 43-G, and vertexes of the sloped surfaces 44-G are connected by a flat surface 57 parallel to an X-axis direction. An angle θ6 formed by the flat surface 57 and each of the sloped surfaces 44-G in the bottom portion 43-G is larger than the angle (see FIG. 15) formed by the sloped surfaces 44 of the bottom portion 43 in the first embodiment. Thus, when the lamp clip 18-G is molded of resin, a molten resin material easily uniformly flows into a mold, thereby reducing poor molding.

### Ninth Embodiment

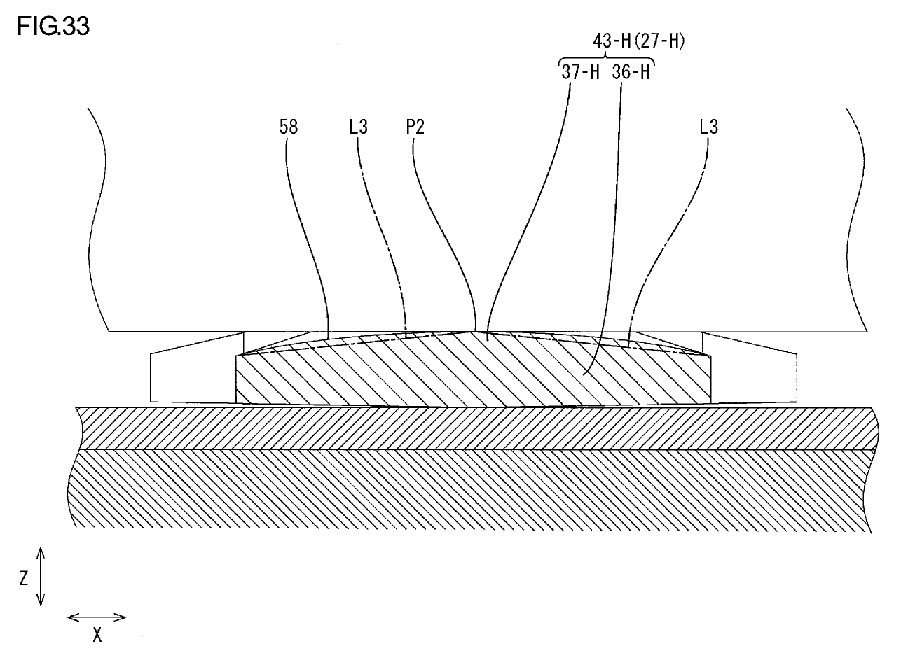

A ninth embodiment of the present invention will be described with reference to FIG. 33. In the ninth embodiment, a sectional shape of a bottom portion 43-H of a lamp gripping portion 28-H is changed. In the ninth embodiment, the same components as in the first embodiment are denoted by the same reference numerals with a suffix -H added to the ends, and overlapping descriptions on structures, operations, and advantages will be omitted.

A raised portion 37-H that constitutes a bottom portion 43-H has a substantially arcuate sectional shape as shown in FIG. 33. An arcuate curved surface 58 is formed over the entire circumferential surface of the raised portion 37-H of the bottom portion 43-H. The curved surface 58 is expanded outward of an outside of a line L3 connecting opposite end positions in a width direction of the raised portion 37-H and a vertex P2. When a light is reflected by the curved surface 58, the reflected light is appropriately scattered without traveling in a particular direction. This is suitable for providing uniform reflection efficiency. Also, higher strength can be obtained than a case where a raised portion is formed to be recessed inward of the line L3.

### Tenth Embodiment

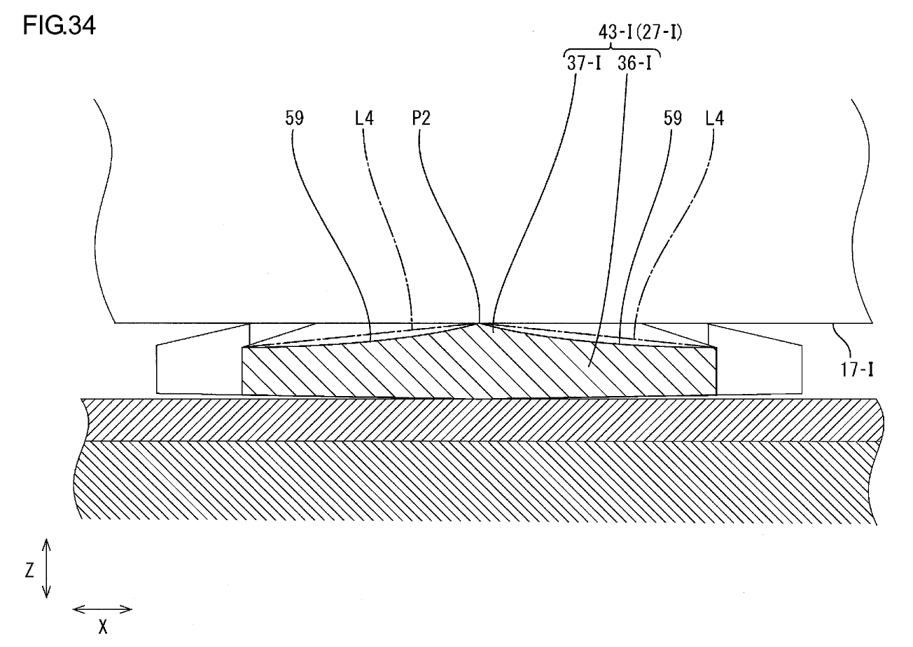

A tenth embodiment of the present invention will be described with reference to FIG. 34. In the tenth embodiment, a sectional shape of a bottom portion 43-I of a lamp gripping portion 28-I is changed. In the tenth embodiment, the same components as in the first embodiment are denoted by the same reference numerals with a suffix -I added to the ends, and overlapping descriptions on structures, operations, and advantages will be omitted.

A raised portion 37-I that constitutes the bottom portion 43-I is formed to have a substantially angular sectional shape with opposite side surfaces being recessed in an arcuate shape as shown in FIG. 34. On opposite side surfaces of the raised portion 37-I of the bottom portion 43-I, a pair of arcuate curved surfaces 59 recessed inward of an inside of a line L4 connecting opposite end positions in a width direction of the raised portion 37-I and a vertex P2 are formed. The bottom portion 43-I is tapered toward the vertex P2 by the curved surfaces 59. This can ensure a large gap between a cold cathode tube 17-I and the bottom portion 43-I, thereby further improving light taking efficiency. Also, material costs can be reduced as compared with a case where the curved surfaces 59 are expanded outward of the line L4.

### Eleventh Embodiment

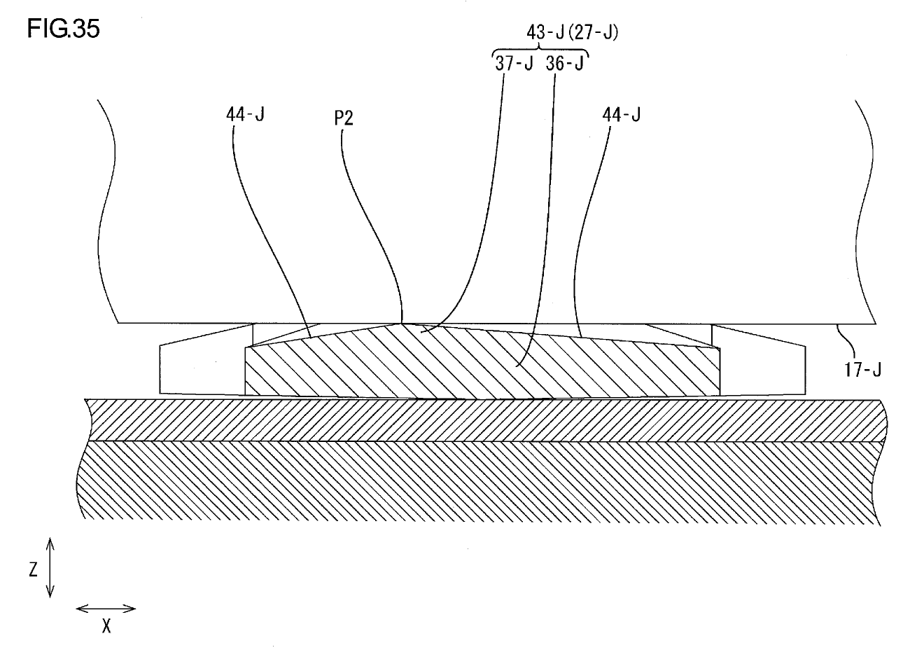

An eleventh embodiment of the present invention will be described with reference to FIG. 35. In the eleventh embodiment, a sectional shape of a bottom portion 43-J of a lamp gripping portion 28-J is changed. In the eleventh embodiment, the same components as in the first embodiment are denoted by the same reference numerals with a suffix -J added to the ends, and overlapping descriptions on structures, operations, and advantages will be omitted.

A raised portion 37-J that constitutes a bottom portion 43-J has a triangular sectional shape asymmetrical in a width direction as shown in FIG. 35. Thus, a pair of sloped surfaces 44-J formed on opposite side surfaces of the raised portion 37-J of the bottom portion 43-J have different slope angles. Thus, between a cold cathode tube 17-J and the bottom portion 43-J, different amounts of light can be emitted from a vertex P2 of the bottom portion 43-J to the left and right in FIG. 35, which is suitable for a backlight unit that desires such design. Alternatively, this design can be used for adding an intensity distribution correction function to the backlight unit. In this case, the vertex P2 is in an eccentric position from a middle in a width direction of the bottom portion 43-J.

### Twelfth Embodiment

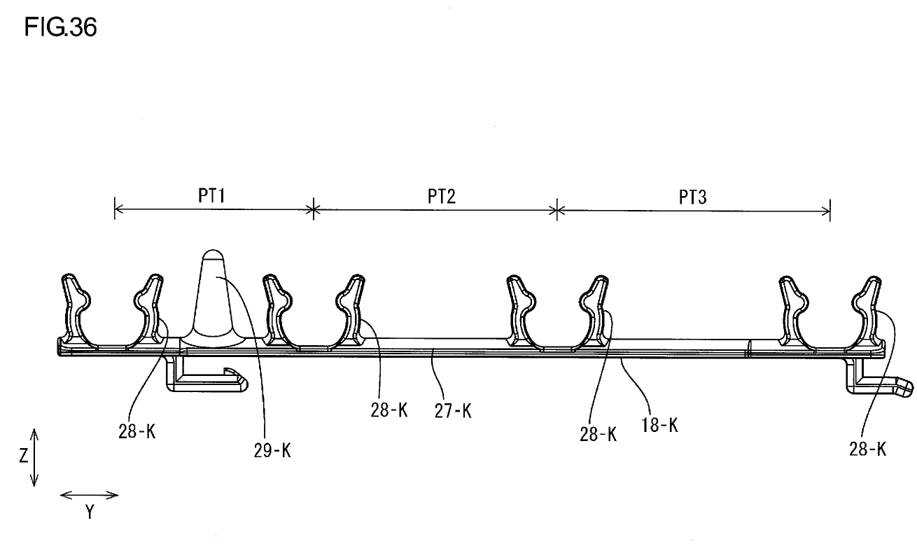

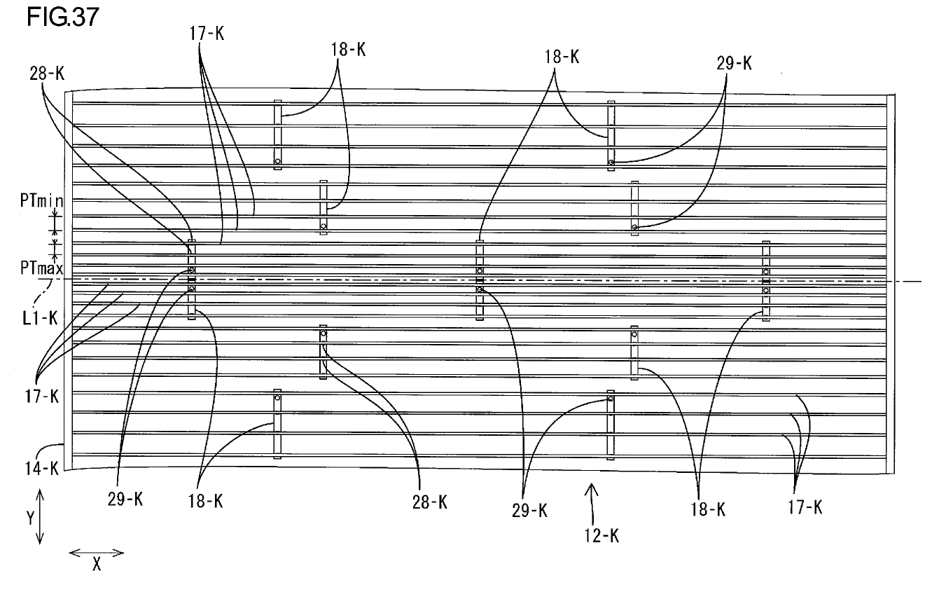

A twelfth embodiment of the present invention will be described with reference to FIG. 36 or 37. In the twelfth embodiment, an arrangement of each lamp gripping portion 28-K on a lamp clip 18-K is changed. In the twelfth embodiment, the same components as in the first embodiment are denoted by the same reference numerals with a suffix -K added to the ends, and overlapping descriptions on structures, operations, and advantages will be omitted.

As shown in FIG. 36, a plurality of (four) lamp gripping portions 28-K are arranged in positions spaced apart in a length direction of a main body 27-K with different pitches (spaces) PT1 to PT3 between the lamp gripping portions 28-K. Specifically, the pitches PT1 to PT3 between the adjacent lamp gripping portions 28-K are smaller in positions closer to an edge portion of the main body 27-K on a side of a support pin 29-K, and larger in positions closer to an edge portion on a side opposite the support pin 29-K. Specifically, distribution density of the lamp gripping portions 28-K on the lamp clip 18-K is set to be higher on the side closer the eccentrically placed support pin 29-K.

As shown in FIG. 37, a plurality of lamp clips 18-K having the above-described structure are mounted to a chassis 14-K, and the lamp clips 18-K are designed with different pitches PT1 to PT3 between the lamp gripping portions 28-K depending on mounting positions to the chassis 14-K. Specifically, a maximum value PTmax of a pitch between the lamp gripping portions 28-K on the lamp clip 18-K provided close to a reference line L1-K of the chassis 14-K is set to be smaller than a minimum value PTmin of a pitch between the lamp gripping portions 28-K on the lamp clip 18-K mounted to a position farther from the reference line L1-K than the above-described lamp clip 18-K. Specifically, distribution density of the lamp gripping portions 28-K on the chassis 14-K is set to be higher on the side closer to the reference line L1-K.

With such design, when each cold cathode tube 17-K is mounted to each lamp gripping portion 28-K, the pitches between adjacent cold cathode tubes 17-K are unequal, distribution density of the cold cathode tubes 17-K is higher on the side closer to the reference line L1-K on the chassis 14-K, and distribution density of the cold cathode tubes 17-K is lower on the side closer to the opposite end sides. This can improve intensity on a screen middle side of the backlight unit 12-K, and each support pin 29-K placed closer to the screen middle can satisfactorily support a diffuser plate.

### Thirteenth Embodiment

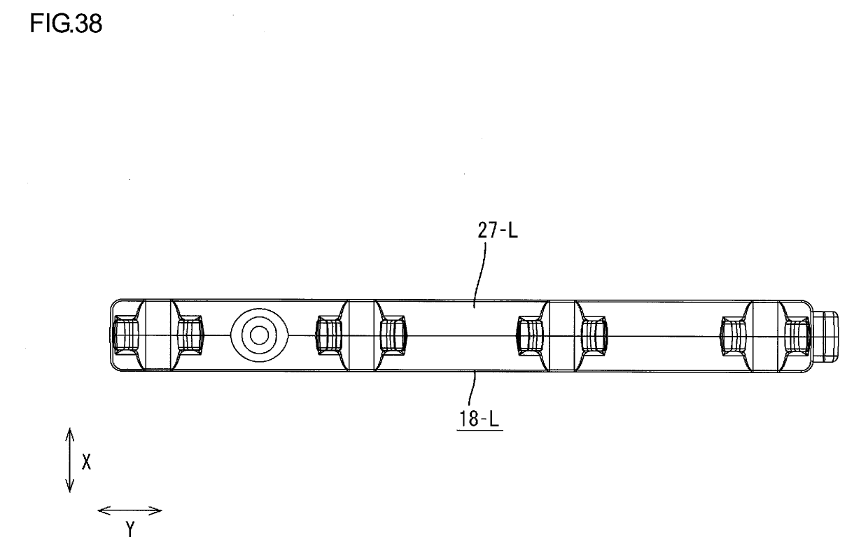

A thirteenth embodiment of the present invention will be described with reference to FIG. 38. In the thirteenth embodiment, a shape of a main body 27-L is changed. In the thirteenth embodiment, the same components as in the first embodiment are denoted by the same reference numerals with a suffix -L added to the ends, and overlapping descriptions on structures, operations, and advantages will be omitted.

As shown in FIG. 38, the main body 27-L has a fixed width over the entire length. This can simplify a shape of a lamp clip 18-L and reduce mold production costs or the like.

### Fourteenth Embodiment

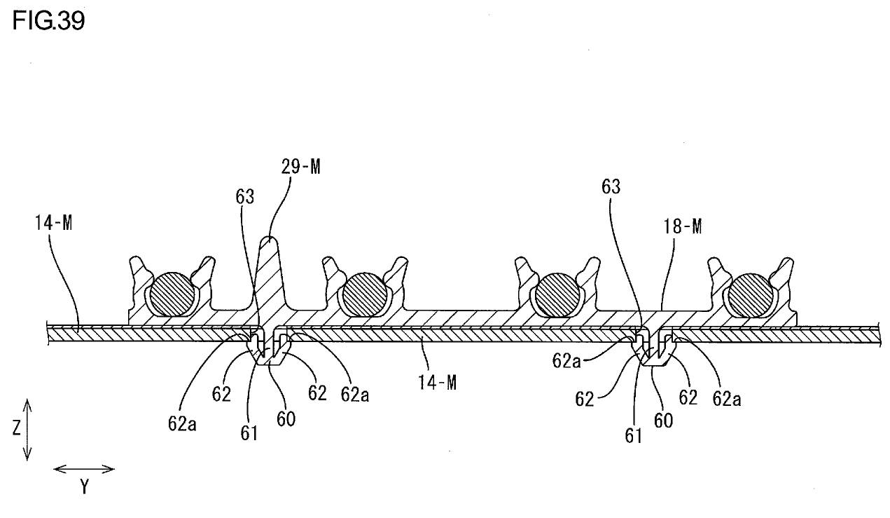

A fourteenth embodiment of the present invention will be described with reference to FIG. 39. In the fourteenth embodiment, a mounting portion 60 is changed. In the fourteenth embodiment, the same components as in the first embodiment are denoted by the same reference numerals with a suffix -M added to the ends, and overlapping descriptions on structures, operations, and advantages will be omitted.

As shown in FIG. 39, the mounting portion 60 includes a base portion 61 protruding from a back surface of a main body 27-M, and a pair of locking pieces 62 bent from a protruding end of the base portion 61 toward the main body 27-M to oppose the base portion 61. The locking piece 62 is elastically deformable so as to be close to the base portion 61, and a stepped locking surface 62a is formed in a tip portion thereof. A mounting hole 63 in a chassis 14-M has substantially the same diameter as a space between the locking surfaces 62a of the locking pieces 62.

When a lamp clip 18-M is pressed in the chassis 14-M from a front side along a Z-axis direction, each mounting portion 60 is inserted into each mounting hole 63, and the locking piece 62 is once elastically deformed. Then, when the lamp clip 18-M is pressed to a normal depth, the mounting portion 60 protrudes on a back side of the chassis 14-M, the locking piece 62 is restored, and the locking surface 62a is locked to a rim of the mounting hole 63 in the chassis 14-M from the back side. Thus, the lamp clip 18-M is held in a mounting state to the chassis 14-M. As such, besides the sliding mounting type lamp clip 18 described in the first embodiment, the insertion mounting type lamp clip 18-M in this embodiment can preferably reduce luminance unevenness. The mounting portion 60 is provided directly below the support pin 29-M, thereby improving workability in mounting the lamp clip 18-M to the chassis 14-M.

### Fifteenth Embodiment

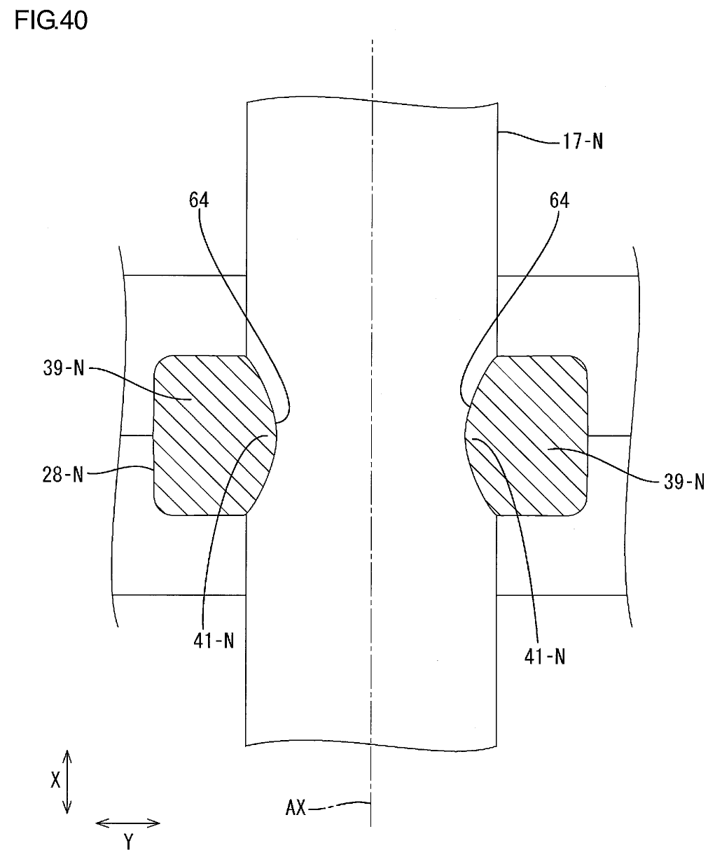

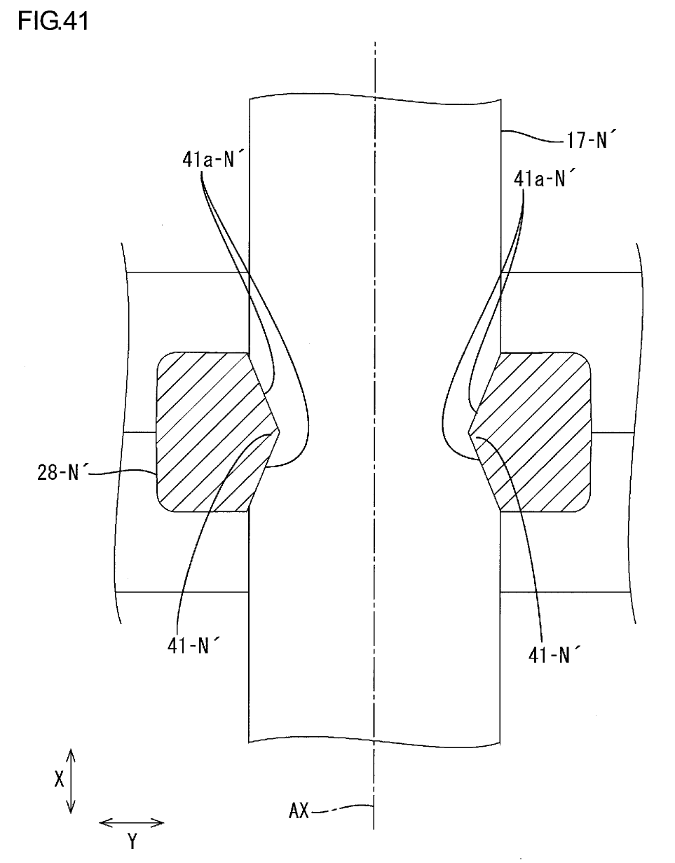

A fifteenth embodiment of the present invention will be described with reference to FIG. 40 or 41. In the fifteenth embodiment, a shape of a lamp gripping portion 28-N is changed. In the fifteenth embodiment, the same components as in the first embodiment are denoted by the same reference numerals with a suffix -N added to the ends, and overlapping descriptions on structures, operations, and advantages will be omitted.

As shown in FIG. 40, a holding protrusion 41-N of the lamp gripping portion 28-N has an inner peripheral surface formed with an arcuate curved surface 64, and is thus tapered toward a cold cathode tube 17-N. Specifically, the holding protrusion 41-N has a width progressively decreasing from an outer end side toward an inner end side, that is, toward a central axis AX of the cold cathode tube 17-N. An arm portion 39-N is also tapered continuously with the holding protrusion 41-N. This can reduce a covering area of the cold cathode tube 17-N by the lamp gripping portion 28-N, and ensure a sufficient amount of light provided by the cold cathode tube 17-N.

As a further variation aspect, as shown in FIG. 41, a holding protrusion 41-N′ may have a substantially triangular sectional shape, and tapered surfaces 41a-N′ may be directly connected. An angle formed by the tapered surfaces 41a-N′ is preferably an acute angle. This can further reduce a covering area of a cold cathode tube 17-N′ by a lamp gripping portion 28-N′, which is further suitable for increasing an amount of light.

### Further Embodiments

The present invention is not limited to the embodiments described in the above descriptions and the drawings, and for example, the following embodiments also fall within a technical scope of the present invention.

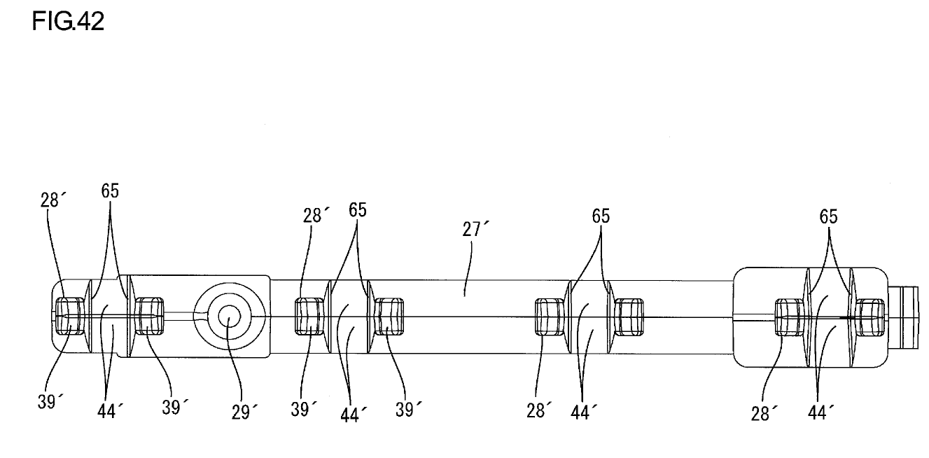

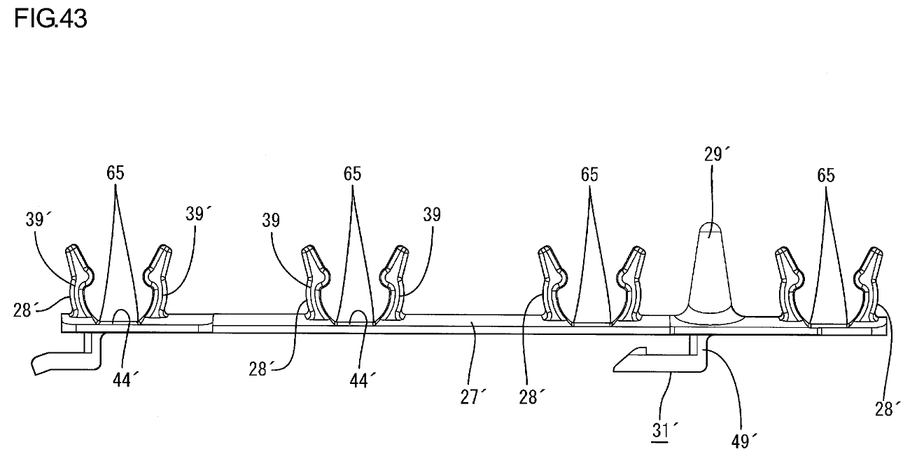

(1) Besides the above-described embodiments, the number, shape, arrangement of lamp gripping portions on a lamp clip may be appropriately changed. Specifically, it may be allowed that a shape of an inner peripheral surface of a lamp gripping portion 28′ is changed, and as shown in FIGS. 42 and 43, auxiliary sloped surfaces 65 sloping upward toward an arm portion 39′ are provided in opposite side end positions of sloped surfaces 44′ of an inner peripheral surface of the lamp gripping portion 28′. The number of lamp gripping portions may be three or less or five or more. A pair of arm portions that constitute the lamp gripping portion may be asymmetrical to each other. The lamp gripping portion may include one arm portion, and a cold cathode tube may be laterally mounted along a plate surface of a main body. The lamp gripping portion may be placed in a position at a predetermined height raised from the main body.

(2) In the first and fifteenth embodiments, the entire lamp gripping portion is tapered to form the tapered surface and the extended tapered surface, but the extended tapered surface may be omitted except a tapered surface formed on a holding protrusion, that is, only the holding protrusion may be tapered in the present invention. Further, for example, the tapered surface and the extended tapered surface may be left at the center of the cold cathode tube in the lamp gripping portion, specifically, in a region on a front side of a reference surface parallel to the chassis passing through the center of the cold cathode tube, but the extended tapered surface may be omitted in a region on a back side. This can ensure at least a sufficient amount of light emitted from the cold cathode tube to the front side, and a dark portion is less likely to be recognized.

(3) In the first embodiment, the sloped surface (relief surface) and the extended sloped surface (extended relief surface) are formed over the entire inner and outer peripheral surfaces of the lamp gripping portion, but the extended sloped surface may be omitted except an sloped surface formed on a bottom surface in the present invention. Further, a forming range of the extended sloped surface in the lamp gripping portion may be appropriately changed. Both the sloped surface and the extended sloped surface may be omitted.

(4) Besides the above-described embodiments, the number, shape, arrangement of support pins on a lamp clip may be appropriately changed. Specifically, a plurality of support pins may be provided. The support pin may be formed into a pyramidal shape. The support pin may be provided in an eccentric position in a width direction of a main body. The support pin may be provided in a middle position in a length direction of the main body.

(5) Besides the above-described embodiments, the number, shape, arrangement of mounting portions on a lamp clip may be appropriately changed. Specifically, placement of a second mounting portion 31′ may be changed so that, as shown in FIGS. 42 and 43, a base portion 49′ of the second mounting portion 31′ is connected to a position directly on a back side of a support pin 29′ of a main body 27′. Only one, or three or more mounting portions may be provided. It may be allowed that the first mounting portion does not protrude laterally from an edge portion of the main body. With the change of the mounting portion, the number, shape, arrangement of mounting holes in a chassis and insertion holes in a reflective sheet may be appropriately changed.

(6) Also, for example, a piece that constitutes each mounting portion may be extended along the width direction of the main body, and the main body may be slid along the width direction and thus attached to and detached from the chassis.

(7) Besides the above-described embodiments, the shape of the main body on the lamp clip may be appropriately changed. Specifically, the main body may be formed into a square shape on the plan view, a circular or an oval shape, or a polygonal shape other than a rectangular shape on the plan view in the present invention. Further, the main body may be mounted to the chassis with a length direction being in parallel with a reference line (length direction of a cold cathode tube). In this case, a plurality of lamp gripping portions may grip one cold cathode tube.

(8) In the first embodiment, the raised portion has the pair of sloped surfaces along the width direction, but a pair of sloped surfaces along the length direction may be added on opposite edge portions in the length direction of the main body in the present invention. The sectional shape of the raised portion may be appropriately changed besides the shapes in the first, sixth and seventh embodiments. At this time, the raised portion may have an asymmetrical sectional shape. The raised portion together with the sloped surfaces may be omitted. The base or the raised portion may be omitted from the main body.

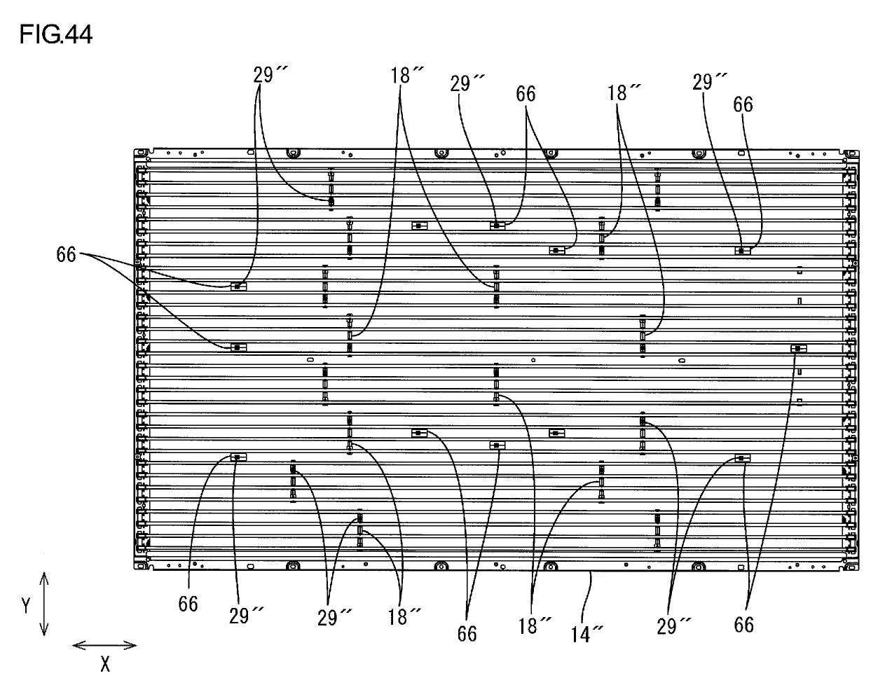

(9) Besides the above-described embodiments, the number and arrangement of lamp clips provided on the chassis may be appropriately changed. Specifically, as shown in FIG. 44, two lamp clips 18″ may be arranged along a long side direction of a chassis 14″ in a position adjacent to a reference line. At this time, a support part 66 including a configuration without a lamp gripping portion 28″ from a lamp clip 18″ and having only a support pin 29″ may be provided separately from the lamp clip 18″. Further, the number of provided lamp clips or spaces between the lamp clips in the long side direction of the chassis may be changed, and also those in the short side direction of the chassis may be changed.

(10) In the above-described embodiments, the reference line is set in parallel with the length direction of the cold cathode tube, but the reference line may be set perpendicularly to the length direction of the cold cathode tube in the present invention.

(11) In the above-described embodiments, the cold cathode tube is used as a light source, but for example, a different type of light source such as a hot cathode tube may be used in the present invention.

(12) In the above-described embodiments, the chassis is formed of sheet metal, but may be molded of resin.

(13) In the above-described embodiments, the TFT is used as the switching element of the liquid crystal display device, but the present invention may be applied to a liquid crystal display device using a switching element other than the TFT (for example, thin film diode (TFD)), and may be applied to a liquid crystal display device for a monochrome display other than a liquid crystal display device for a color display.

(14) In the above-described embodiments, the liquid crystal display device using a liquid crystal panel as a display panel is exemplified, but the present invention may be applied to a display device using a different type of display panels.

(15) In the above-described embodiments, the television receiver apparatus including the tuner is exemplified, but the present invention may be applied to a display device without a tuner.

(16) In the first, eighth, tenth and eleventh embodiments, the pair of sloped surfaces or curved surfaces with a vertex in the middle position in the width direction are formed on the bottom surface of the lamp gripping portion, but for example, one sloped surface or curved surface with a vertex set at one edge portion of opposite edge portions in the width direction of the lamp gripping portion and sloping downward from the vertex toward the other edge portion may be formed in the present invention.

(17) In the first and fourth embodiments, the first mounting portion and the second mounting portion have different widths and lengths, and correspondingly thereto, the first mounting hole and the second mounting hole have different widths and lengths, but for example, the first mounting portion and the second mounting portion, and the first mounting hole and the second mounting hole may have the same length and different widths, or the same width and different lengths in the present invention. Also in this case, sizes of the mounting portions and the mounting holes are different in a direction perpendicular to an inserting direction of the first mounting portion and the second mounting portion into the first mounting hole and the second mounting hole, and a larger mounting portion is larger than a smaller mounting hole and cannot be inserted thereinto, thereby the lamp clip is less likely to be mounted in a wrong mounting direction.

(18) In the first and fourth embodiments, the pieces of the mounting portions have different widths and lengths, but it may be allowed that the pieces have the same width and length, at least one of widths (sizes in the X-axis direction in the drawings) or thicknesses (sizes in the Y-axis direction in the drawings) of the base portions are different, and the sizes of the mounting holes are different corresponding thereto in the present invention. In short, it is sufficient that the sizes in the direction perpendicular to the inserting direction of the mounting portions into the mounting holes are different.

(19) As a further variation aspect of the fourth embodiment, a control portion partially protruding in a length direction may be provided in at least one of the mounting portions, and a notch that allows insertion of the control portion may be provided in a mounting hole corresponding to the mounting portion having the control portion among the mounting holes.

(20) In the above-described embodiments, the case where the mounting portion is provided in the lamp clip, the mounting hole is provided in the chassis, and the insertion hole is provided in the reflective sheet is described as a mounting structure of the lamp clip, but the mounting portion, the mounting hole, and the insertion hole may be removed and the lamp clip may be directly or indirectly mounted to the chassis by a different mounting structure. The different mounting structure includes, for example, a structure in which a double-sided tape is interposed between the main body and the chassis or the reflective sheet.

(21) In the above-described embodiments, the raised portion that constitutes the main body has the angular shape with the pair of sloped surfaces or curved surfaces, but for example, a plurality of angular portions may be arranged on the front side of the base to form a raised portion having three or more sloped surfaces or curved surfaces in the present invention. The raised portion may have a shape other than an angular shape in the present invention.

1. A lamp holder comprising a lamp gripping portion for holding a tubular lamp, the lamp gripping portion having an open-end ring shape with a tapered portion that tapers toward an end thereof located on a lamp holding side.

2. The lamp holder according to claim 1, wherein the tapered portion is located at a part of the lamp gripping portion that is to cover a part of the lamp on a light output side and tapers toward the end in a view from the light output side.

3. The lamp holder according to claim 1, wherein the tapered portion gradually decreases in size that measures in a direction corresponding to a length direction of the lamp toward a line corresponding to a central axis of the lamp.

4. The lamp holder according to claim 1, further comprising a main body to be mounted to a mounting member, wherein:
the lamp gripping portion includes a pair of arm portions rising from the main body and holding protrusions that protrude from distal ends of the arm portions toward the lamp holding side for retaining the lamp in place; and
the holding protrusions taper toward respective ends thereof.

5. The lamp holder according to claim 4, wherein the tapered portion of the arm portion of the lamp gripping portion is located in an area that is to be on the further side from the mounting member than where a center of the lamp is to be aligned.

6. The lamp holder according to claim 5, wherein the arm portions have tapered portions over an entire length.

7. The lamp holder according to claim 1, wherein the tapered portions have sloped surfaces on end surfaces of the lamp holding portions in a direction corresponding to the length direction of the lamp.

8. The lamp holder according to claim 1, wherein the tapered portions have curved surfaces on end surfaces of the lamp gripping portions in a direction corresponding to the length direction of the lamp.

9-13. (canceled)

14. The lamp holder according to claim 10, further comprising a main body to be mounted to a mounting member, wherein:
the lamp gripping portion continues from the main body; and
the bottom surface is located lower than a surface of the main body on the further side from the mounting member.

15. The lamp holder according to claim 10, further comprising a main body to be mounted to a mounting member, wherein:
the lamp gripping portion includes a pair of arm portions rising from the main body and holding protrusions that protrude from distal ends of the arm portions toward the lamp holding side so as to retain the lamp in place, and so as to support the lamp at three support points by the bottom surface and the holding protrusions with circumferentially extending gaps between the support points.

16. The lamp holder according to claim 1, further comprising a main body to be mounted to a mounting member, wherein:
the lamp gripping portion continues from the main body; and
the main body includes a base having a substantially even thickness and a raised portion rising from the base toward the side to be away from the mounting member.

17. (canceled)

18. The lamp holder according to claim 16, wherein:
the main body includes a mounting portion to be inserted in a mounting hole formed in the mounting member and an insertion hole larger than the mounting hole formed in a reflective member that is provided on the mounting member so as to face the main body so that a rim of the mounting hole is sandwiched between the mounting portion and the main body, the mounting portion protruding so as to extend toward the mounting member, and
the base is constructed so as to cover the insertion hole and the mounting hole.

19. The lamp holder according to claim 18, wherein:
the main body has a rectangular shape elongated in one direction and includes a wide portion and a narrow portion having different widths; and
the mounting portion is provided in the wide portion.

20. The lamp holder according to claim 16, wherein:
the main body has a rectangular shape elongated in one direction; and
the raised portion has a shape that gradually decreases in size in a short-side direction of the maim body toward a vertex.

21. The lamp holder according to claim 16, wherein:
the main body has a rectangular shape elongated in a direction perpendicular to a direction corresponding to the length direction of the lamp,
the main body is wider than the lamp gripping portion; and
the raised portion is provided so as to be opposite the lamp.

22. The lamp holder according to claim 16, wherein a thickness of the raised portion from the vertex to a bottom is larger than a thickness of the base.

23. An illumination device comprising:
a lamp holder according to claim 1;
a mounting member to which the lamp holder is mounted; and
a plurality of tubular lamps housed in the mounting member and held by the lamp holder.

24. A display device comprising:
an illumination device according to claim 23; and
a display panel provided in front of the illumination device.

25. The display device according to claim 24, wherein the display panel is a liquid crystal panel constructed such that a liquid crystal is sealed between a pair of substrates.

26. A television receiver apparatus comprising a display device according to claim 24.
